(19) United States
(12) Patent Application Publication
(10) Pub. No.: US 2007/0274360 A1
(43) Pub. Date: Nov. 29, 2007

(54) Semiconductor laser element and semiconductor laser device

(75) Inventors: Daijiro Inoue, Kyoto-city (JP); Yasuyuki Bessho, Uji-city (JP); Masayuki Hata, Osaka (JP)

Correspondence Address: NDQ&M WATCHSTONE LLP, 1300 EYE STREET, NW, SUITE 1000 WEST TOWER, WASHINGTON, DC, 20005, US

(73) Assignee: Sanyo Electric Co., Ltd., Moriguchi (JP)

(21) Appl. No.: 11/710,922

(22) Filed: Feb. 27, 2007

(30) Foreign Application Priority Data
Feb. 28, 2006 (JP) P2006-053628
Dec. 28, 2006 (JP) P2006-356583

(51) Int. Cl. H01S 5/00

(52) U.S. Cl. 372/49.01

(57) ABSTRACT

A semiconductor laser element includes a semiconductor layer, an insulating layer and an electrode. The semiconductor layer is formed on a substrate, and includes a raised portion extending along a predetermined direction and flat portions provided on outer sides in a width direction of the raised portion. The insulating layer is formed on upper surfaces of the flat portions and side surfaces of the raised portion. The electrode includes a first portion provided along the predetermined direction on the raised portion and a second portion including a plurality of protruding portions protruding outward from the first portion in the width direction of the raised portion. A gap through which the insulating layer is exposed is provided between each adjacent two of the plurality of protruding portions.

### CROSS REFERENCE TO RELATED APPLICATIONS

This application is based upon and claims the benefit of priority from prior Japanese Patent Application No. 2006-53628, filed on Feb. 28, 2006; and prior Japanese Patent Application No. 2006-356583, filed on Dec. 28, 2006; the entire contents of which are incorporated herein by reference.

### BACKGROUND OF THE INVENTION

1. Field of the Invention

The present invention relates to a semiconductor laser element and a semiconductor laser device. In particular, the present invention relates to a semiconductor laser element and a semiconductor laser device, which include a current blocking layer made of an insulating material.

2. Description of the Related Art

In recent years, nitride-semiconductor-based semiconductor laser elements have been commercialized which are used as light sources for high-density recording in optical disk systems. In order to improve recording rates and to deal with multilayer recording media, laser power has been remarkably increased. As such nitride semiconductor laser elements for optical disk systems, semiconductor laser elements having ridge waveguide structures are generally used. In semiconductor laser elements having ridge waveguide structures, laser light is confined by a current blocking layer made of a transparent insulating material. To achieve an improvement in the recording rate of an optical recording system using such a semiconductor laser element, it is essential to increase the operating speed of the semiconductor laser element in addition to increasing the laser power.

The basic structure of a semiconductor laser element having this ridge waveguide structure is as shown in FIG. 1. That is, the semiconductor laser element includes: a first cladding layer 102 of a first conductivity type formed on a substrate 101 of the first conductivity type; an active layer 103 formed on the first cladding layer 102; a second cladding layer 104 of a second conductivity type, which is formed on the active layer 103, and which has a raised portion (a ridge portion) in a central portion thereof, a contact layer 105 formed on the raised portion of the second cladding layer 104; and a current blocking layer 106 formed on side surfaces of the raised portion of the second cladding layer 104, side surfaces of the contact layer 105, and flat portions of the second cladding layer 104. On the front and back surfaces of the above-described structure, electrodes 107 and 108 are provided which form ohmic contacts to the second conductivity type semiconductor and the first conductivity type substrate, respectively.

This current blocking layer 106 has both a role as a current barrier layer for supplying current only to the ridge portion and the function of providing a refractive index difference with respect to the ridge portion to achieve optical confinement. Moreover, in order to achieve high-speed operation of the semiconductor laser element, for the current blocking layer 106, used is an insulating material, in which the value of parasitic capacitance occurring in the current blocking layer 106 is easily reduced, and which has a low dielectric constant.

High-frequency operation characteristics of a semiconductor laser element are usually discussed using an equivalent circuit. The present semiconductor laser element can be represented in an abbreviated manner by an equivalent circuit such as shown in FIG. 2. That is, capacitances C1 and C2 produced by the current blocking layer on both sides are in parallel with R1 corresponding to the resistance of the ridge portion, and R2 corresponding to the total resistance of the flat portions of the second cladding layer and the lower layers is connected in series with the foregoing components.

To increase the operating speed, the values of these resistances and capacitances need to be reduced. Of these, the values of the resistances cannot be greatly reduced in most cases, because of constraints of characteristics of materials. On the other hand, the values of the capacitances can be reduced by using a material having a low dielectric constant, reducing the area in which an electrode is formed, or increasing a film thickness. This is because the values of the capacitances are directly proportional to the dielectric constant of the material of the current blocking layer and the electrode formation area on the current blocking layer, and concurrently are inversely proportional to the film thickness of a depleted portion, i.e., the thickness of the current blocking layer made of an insulating material, as expressed by the following equation:
Capacitance Value: C=εS/d
ε: Dielectric Constant of Current Blocking Layer
S: Area of Electrode Formation Region on Current Blocking Layer
d: Thickness of Current Blocking Layer

Among the above-described factors, a method has been studied in which the area of the electrode formation region on the current blocking layer is reduced. In this case, in order to reduce the electrode formation region, a conductive layer pattern is limited only to a narrow region including the current injection region and a portion to which a wire for supplying power is bonded, as shown in FIG. 3.

### SUMMARY OF THE INVENTION

A first aspect of the present invention is a semiconductor laser element including: a semiconductor layer, which is formed on a substrate, and which includes a raised portion extending along a predetermined direction and flat portions provided on outer sides in a width direction of the raised portion; an insulating layer formed on upper surfaces of the flat portions and side surfaces of the raised portion; and an electrode including a first portion provided along the predetermined direction on the raised portion and a second portion including a plurality of protruding portions protruding outward from the first portion in the width direction of the raised portion. The raised portion is a current injection region into which current is injected from the electrode. The plurality of protruding portions are provided on the insulating layer. A gap through which the insulating layer is exposed is provided between each adjacent two of the plurality of protruding portions.

In the first aspect of the present invention, it is preferable that the electrode has a comb-like shape in which end portions of the plurality of protruding portions on outer sides in the width direction of the raised portion are separated from one another.

In the first aspect of the present invention, it is preferable that at least one of the plurality of protruding portions have a shape having a width greater than 10 μm in the predetermined direction.

In the first aspect of the present invention, it is preferable that a width of each of the protruding portions in the predetermined direction is not more than a width of each of the gaps in the predetermined direction.

A second aspect of the present invention is a semiconductor laser element including: a semiconductor layer which is formed on a substrate and which includes a raised portion extending along a predetermined direction and flat portions provided on outer sides in a width direction of the raised portion; an insulating layer formed on upper surfaces of the flat portions and side surfaces of the raised portion; and an electrode including a first portion provided along the predetermined direction on the raised portion and a second portion including a protruding portion protruding outward from the first portion in the width direction of the raised portion. The raised portion is a current injection region into which current is injected from the electrode. The protruding portion is provided on the insulating layer. An island-shaped bonding portion which is apart from the electrode is provided on the insulating layer. The bonding portion is adjacent to the protruding portion.

In the first and second aspects of the present invention, it is preferable that the protruding portion be provided on a side close to a facet from which laser light emitted by the semiconductor layer is emitted.

In the first and second aspects of the present invention, it is preferable that the substrate be any one of a GaN substrate and a sapphire substrate, and that the semiconductor layer be a nitride semiconductor layer having a hexagonal crystal structure.

A third aspect of the present invention is a semiconductor laser device including: the semiconductor laser element according to any one of the first and second aspects; and at least one conductive wire. The conductive wire is connected to some of the plurality of protruding portions.

A fourth aspect of the present invention is a semiconductor laser device including: the semiconductor laser element according to any one of the first and second aspects; and at least one conductive wire. The conductive wire is connected to both the protruding portion and the bonding portion.

### BRIEF DESCRIPTION OF THE DRAWINGS

FIG. 1 is a perspective view (part 1) of a conventional semiconductor laser element.

FIG. 2 is a diagram showing a simple equivalent circuit of the conventional semiconductor laser element.

FIG. 3 is a perspective view (part 2) of a conventional semiconductor laser element.

FIG. 4 is a perspective view of a semiconductor laser element according to a first embodiment.

FIG. 5 is a top view of the semiconductor laser element according to the first embodiment.

FIGS. 6A and 6B are cross-sectional views of the semiconductor laser element according to the first embodiment.

FIG. 7 is a graph showing the delamination occurrence rate of the semiconductor laser element according to the first embodiment.

FIGS. 8A and 8B are cross-sectional views (part 1) for explaining a method of manufacturing a semiconductor laser element according to the first embodiment.

FIGS. 9A and 9B are cross-sectional views (part 2) for explaining the method of manufacturing a semiconductor laser element according to the first embodiment.

FIG. 10 is a schematic diagram of chip side surfaces of the semiconductor laser element according to the first embodiment.

FIG. 11 is a top view (part 1) showing a modified example of the semiconductor laser element according to the first embodiment.

FIG. 12 is a top view (part 2) showing a modified example of the semiconductor laser element according to the first embodiment.

FIG. 13 is a top view (part 3) showing a modified example of the semiconductor laser element according to the first embodiment.

FIG. 14 is a top view (part 4) showing a modified example of the semiconductor laser element according to the first embodiment.

FIG. 15 is a top view (part 5) showing a modified example of the semiconductor laser element according to the first embodiment.

FIG. 16 is a top view (part 6) showing a modified example of the semiconductor laser element according to the first embodiment.

FIG. 17 is a top view (part 7) showing a modified example of the semiconductor laser element according to the first embodiment.

FIG. 18 is a top view (part 8) showing a modified example of the semiconductor laser element according to the first embodiment.

FIG. 19 is a perspective view of a semiconductor laser element according to a second embodiment.

FIG. 20 is a top view of the semiconductor laser element according to the second embodiment.

FIG. 21 is a top view showing a modified example of the semiconductor laser element according to the second embodiment.

FIG. 22 is a top view of a semiconductor laser element according to a third embodiment.

FIGS. 23A and 23B are cross-sectional views of the semiconductor laser element according to the third embodiment.

FIGS. 24A to 24C are cross-sectional views (part 1) for explaining a method of manufacturing a semiconductor laser element according to the third embodiment.

FIGS. 25A and 25B are cross-sectional views (part 2) for explaining the method of manufacturing a semiconductor laser element according to the third embodiment.

FIGS. 26A and 26B are cross-sectional views (part 3) for explaining the method of manufacturing a semiconductor laser element according to the third embodiment.

FIG. 27 is a view showing the structure of a semiconductor laser device according to a fourth embodiment.

FIG. 28 is a view showing the structure of the semiconductor laser device according to the fourth embodiment.

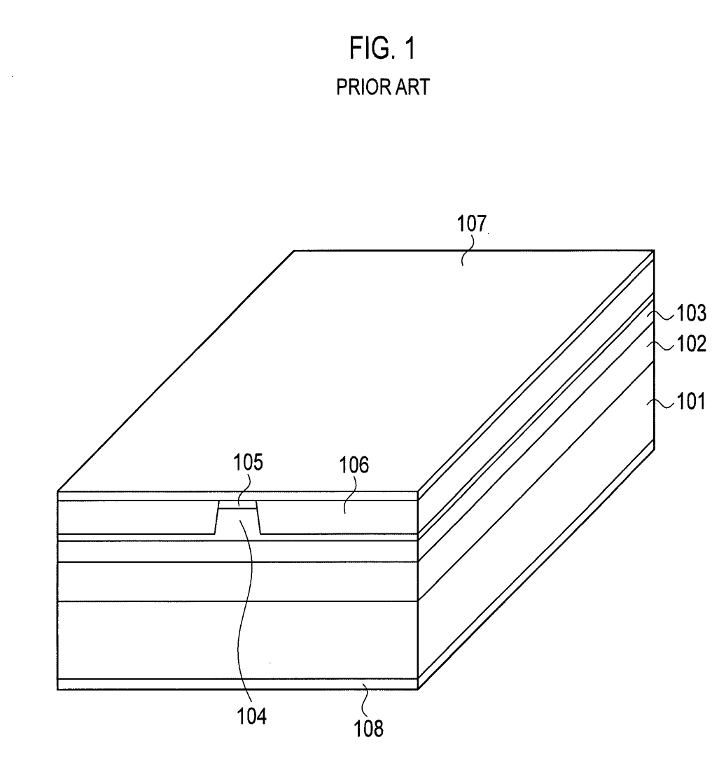

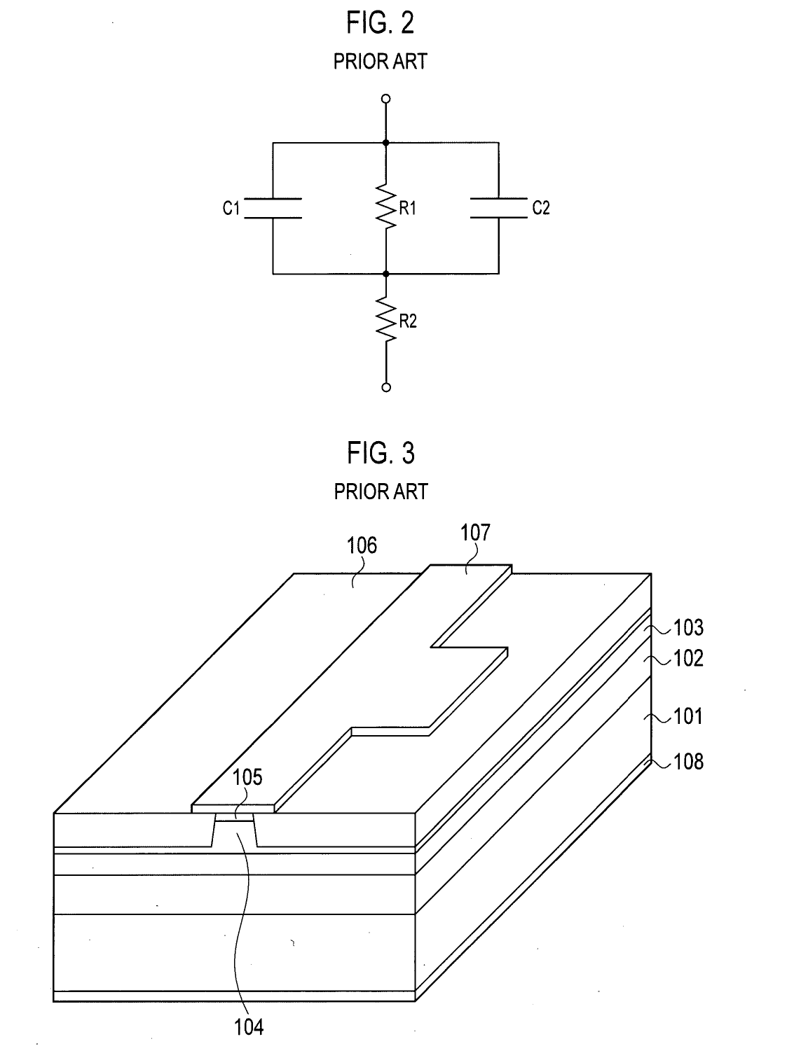

### DETAILED DESCRIPTION OF THE EMBODIMENTS

Next, embodiments of the present invention will be described using the accompanying drawings. In the description below of the drawings, the same or similar components are denoted by the same or similar reference numerals. It should be noted, however, that the drawings are schematic, and that ratios and the like between each dimension differ from actual ones. Accordingly, specific dimensions and the like should be judged in consideration of the description below. Moreover, it is a matter of course that there are portions in which dimensional relationships and ratios differ among drawings.

### First Embodiment

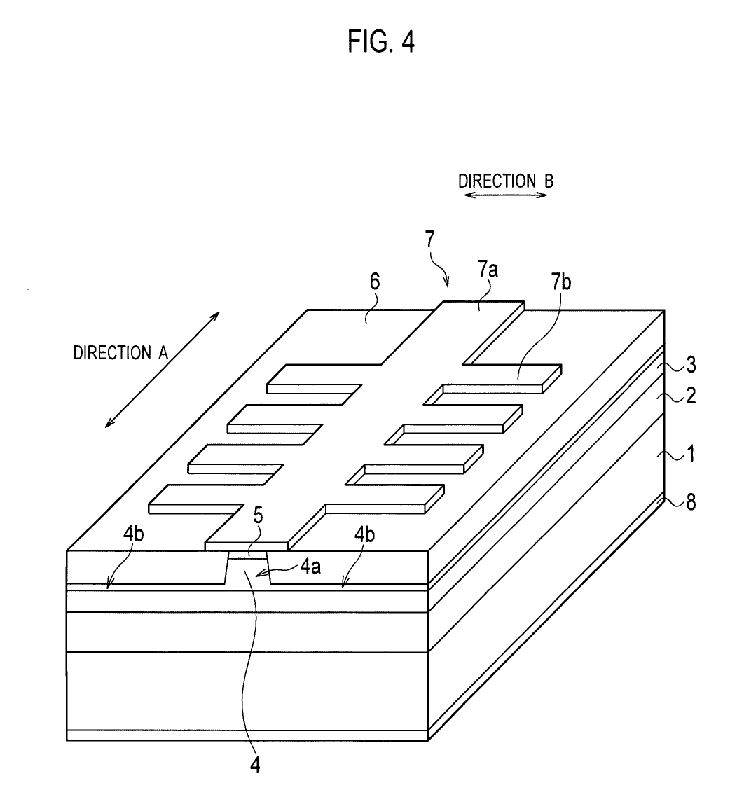

The schematic structure of a semiconductor laser element according to a first embodiment will be described using FIG. 4. The semiconductor laser element includes a semiconductor layer including a first cladding layer 2 of a first conductivity type formed on a substrate 1, an active layer 3 formed on the first cladding layer 2, a second cladding layer 4 of a second conductivity type provided on the active layer 3, and a contact layer 5 provided on a raised portion 4a of the second cladding layer 4. The second cladding layer 4 includes the raised portion 4a extending in direction A, and flat portions 4b provided on outer sides in the width direction (direction B) of the raised portion 4a.

The semiconductor laser element includes a current blocking layer 6, which is formed on the upper surfaces of the flat portions 4b and side surfaces of the raised portion 4a, and which is made of an insulating material. The semiconductor laser element includes an electrode 7 formed on the contact layer 5 and the current blocking layer 6. Here, a straight portion 7a and a plurality of protruding portions 7b are example of “the first portion” and “the second portion” in the claims, respectively.

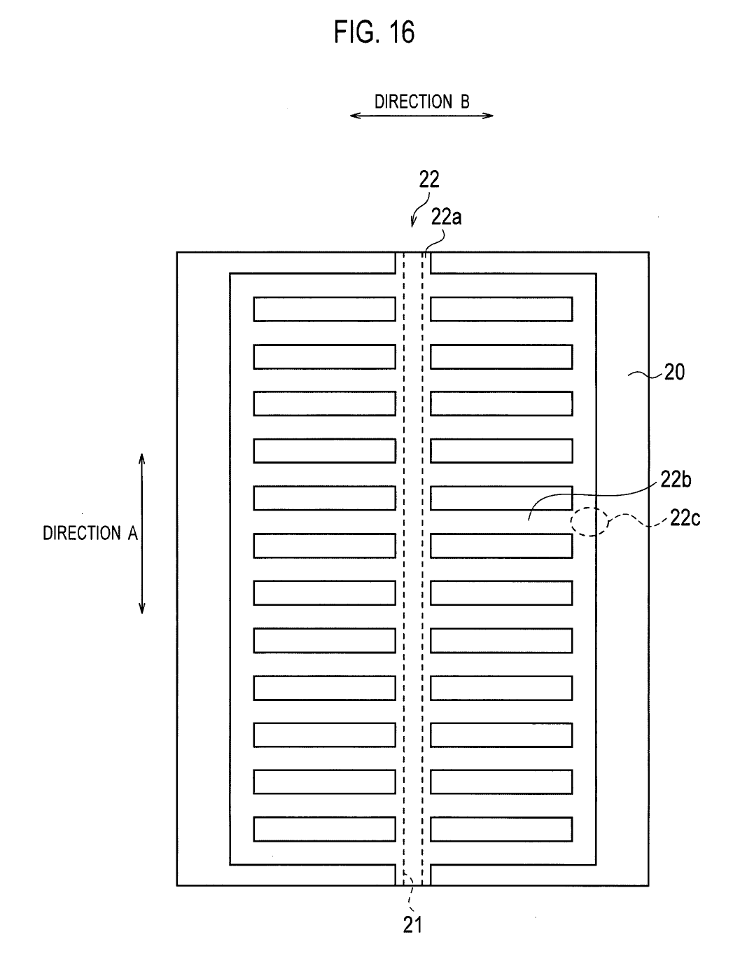

The electrode 7 includes a straight portion 7a and a plurality of protruding portions 7b. The straight portion 7a is provided along direction A on the contact layer 5 (over the raised portion 4a). The plurality of protruding portions 7b protrude outward from the straight portion 7a in the width direction (direction B) of the raised portion 4a. A gap through which the current blocking layer 6 is exposed is provided between each adjacent two of the plurality of protruding portions 7b. Here, the shape of the “gaps” may include not only a shape (FIG. 4) in which end portions of the plurality of protruding portions 7b on outer sides in the width direction (direction B) of the raised portion 4a are not continuous with one another but also a shape in which the end portions of the plurality of protruding portions 7b on outer sides in the width direction (direction B) of the raised portion 4a are continuous with one another. Examples of the latter shape include the shape shown in FIG. 16, which is described later, for example.

In FIG. 4, the protruding portions 7b are provided at regular intervals s along the direction (direction A) in which the raised portion 4a extends. That is, the electrode 7 has a comb-like shape in which the end portions of the plurality of protruding portions 7b on outer sides in the width direction (direction B) of the raised portion 4a are not continuous with one another.

(Structure of Semiconductor Laser Element)

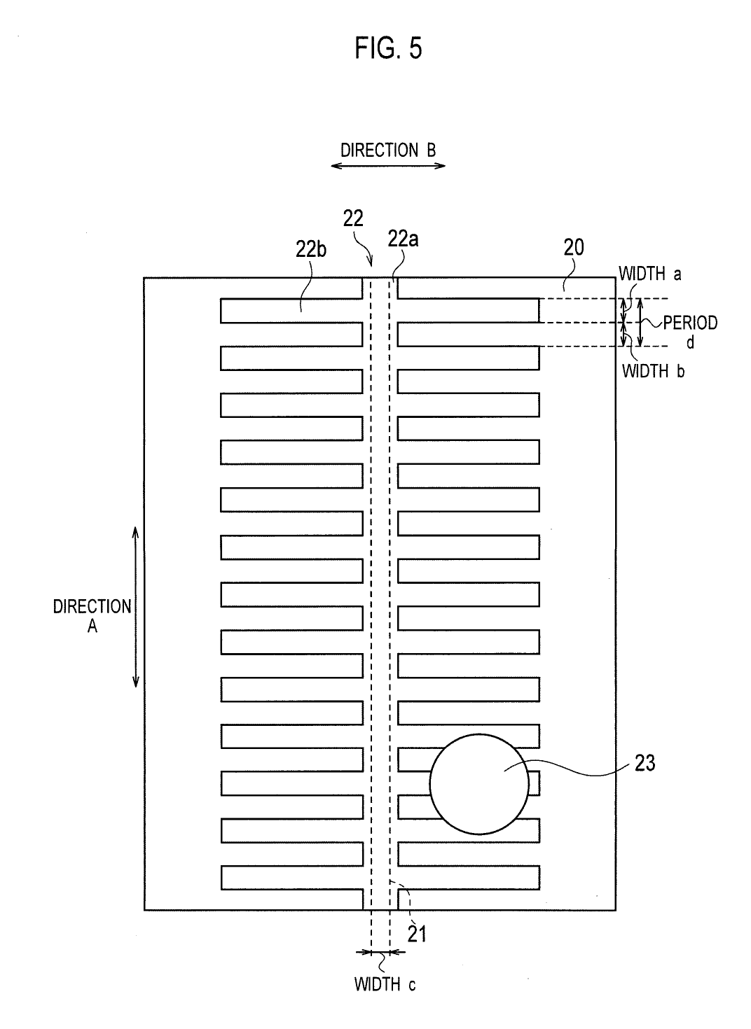

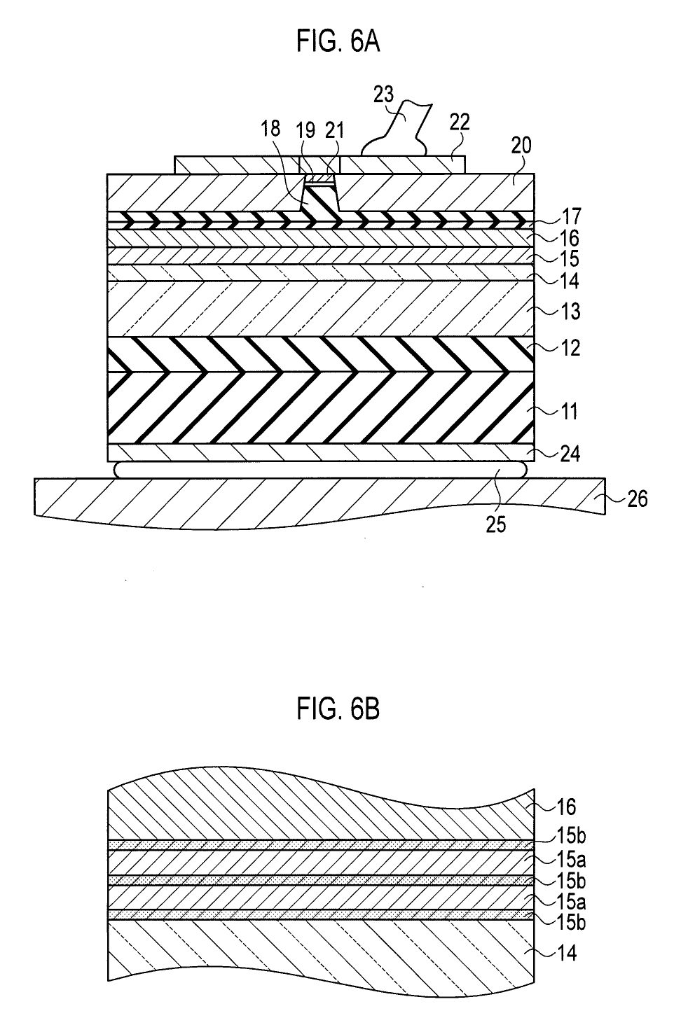

Next, the structure of the semiconductor laser element according to the first embodiment will be described in detail. FIG. 5 is a top view showing the structure of a semiconductor laser element having a wavelength of 400 nm (hereinafter referred to as 400-nm-wavelength semiconductor laser element) (violet LD) which is made of a nitride semiconductor and in which a GaN substrate is used. FIGS. 6A and 6B are cross-sectional views showing the same.

As shown in FIG. 6A, on an n-type hexagonal GaN substrate 11 doped with oxygen, which has a Ga-terminated c-plane surface ((0,0,0,1) surface), a buffer layer 12 is formed, which has a thickness of approximately 1 μm, and which is made of an n-type GaN layer doped with Si. On this buffer layer 12, an n-side cladding layer 13 is formed, which has a thickness of approximately 1.5 μm, and which is made of n-type Al_{0.05}Ga_{0.95}N.

On the n-side cladding layer 13, an n-side optical guide layer 14 is formed, which has a thickness of approximately 50 nm, and which is made of undoped GaN. Furthermore, on the n-side optical guide layer 14, an active layer 15 is formed which has a multiple quantum well (MQW) structure. As shown in FIG. 6B, this active layer 15 has a structure in which two barrier layers 15a and three well layers 15b are alternately laminated. Each barrier layer 15a has a thickness of approximately 15 nm and is made of undoped GaN, and each well layer 15b has a thickness of approximately 4 nm and is made of undoped In_{0.10}Ga_{0.90}N.

On the active layer 15, a p-side optical guide layer 16 is formed, which has a thickness of approximately 100 nm, and which is made of undoped GaN. On the p-side optical guide layer 16, a cap layer 17 is formed, which has a thickness of approximately 20 nm, and which is made of undoped Al_{0.30}Ga_{0.70}N.

On the cap layer 17 made of undoped Al_{0.30}Ga_{0.70}N, a p-side cladding layer 18 is formed, which is made of p-type Al_{0.05}Ga_{0.95}N, and which is doped with Mg. The p-side cladding layer 18 has a maximum thickness of approximately 500 nm, and has a stripe-shaped raised portion having a width of approximately 1.5 μm near the center thereof. On the raised portion, a p-side contact layer 19 is formed, which has a thickness of approximately 10 nm, and which is made of undoped In_{0.05}Ga_{0.95}N. The raised portion of the p-side cladding layer 18 and the p-side contact layer 19 form a ridge portion which serves as a current injection region.

A current blocking layer 20, which has a thickness of approximately 300 nm, and which is made of SiO₂, is formed in a manner covering flat portions of the p-side cladding layer 18, side surfaces of the raised portion of the p-side cladding layer 18, and side surfaces of the p-side contact layer 19. Moreover, a p-side electrode 21 made of Pt/Pd (2 nm/10 nm) is formed on the surface of the p-side contact layer 19. Furthermore, a p-side pad electrode 22, which has a comb-like shape, and which is made of Ti/Au (10 nm/500 nm), is formed on the p-side electrode 21 and the current blocking layer 20.

As shown in FIG. 5, the p-side pad electrode 22 includes a straight portion 22a provided along direction A on the p-side electrode 21 (over the raised portion of the p-side cladding layer 18), and a plurality of protruding portions 22b protruding outward from the straight portion 22a in direction B. A gap is provided between each adjacent two of the plurality of protruding portions 22b. Here, the straight portion 22a and a plurality of protruding portions 22b are example of “the first portion” and “the second portion” in the claims, respectively. A bonding wire 23 made of Au is connected to a portion of the p-side pad electrode 22 so as to supply power to the p-side pad electrode 22 from an external power supply.

In the first embodiment, the width a of each protruding portion 22b and the width b of each gap are equivalent, for example, approximately 15 μm. The width c of the current injection region (p-side electrode 21) is approximately 15 μm. The p-side pad electrode pattern has peripheral dimensions of 200 μm×400 μm. The region in which the bonding wire 23 is in contact with the current blocking layer 20 and the p-side pad electrode 22 is an approximately circular region having a diameter of approximately 70 μm. When a period d denotes the sum of the width a of each protruding portion 22b and the width b of each gap, the period d is preferably not more than ½ of the bond diameter (70 μm) of the bonding wire 23 (e.g., the period d is 30 μm).

Further, as shown in FIG. 6A, on the back surface of the n-type GaN substrate 11, an n-side electrode 24 made of Ti/Pt/Au (10 nm/2 nm/500 nm) is formed. The n-side electrode 24 is connected, through a fusion layer 25 made of AuSn, to a conductive layer 26 for supplying power to the n-side electrode 24. It should be noted that the semiconductor laser element has a width of approximately 300 μm and a depth of approximately 400 μm, and that the surface (facet) from which laser light is emitted is an M-plane surface ({1,−1,0,0} surface).

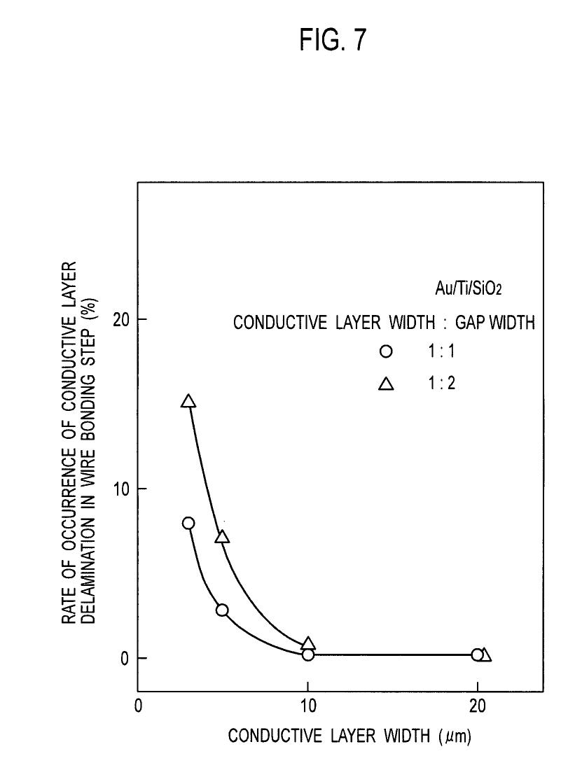

Next, FIG. 7 shows the rate of occurrence of conductive layer delamination in a wire bonding step with respect to the width (the aforementioned width a of each protruding portion 22b) of the comb-shaped conductive layer of the p-side pad electrode 22. FIG. 7 shows that the delamination occurrence rate increases as the conductive layer width decreases. Delamination occurs more often as the ratio (the aforementioned gap width b/the aforementioned protruding portion 22b's width a) of the gap width to the conductive layer width increases. Accordingly, it is desirable that the conductive layer width (protruding portion 22b's width a) be not less than 10 μm.

(Method of Manufacturing Semiconductor Laser Element)

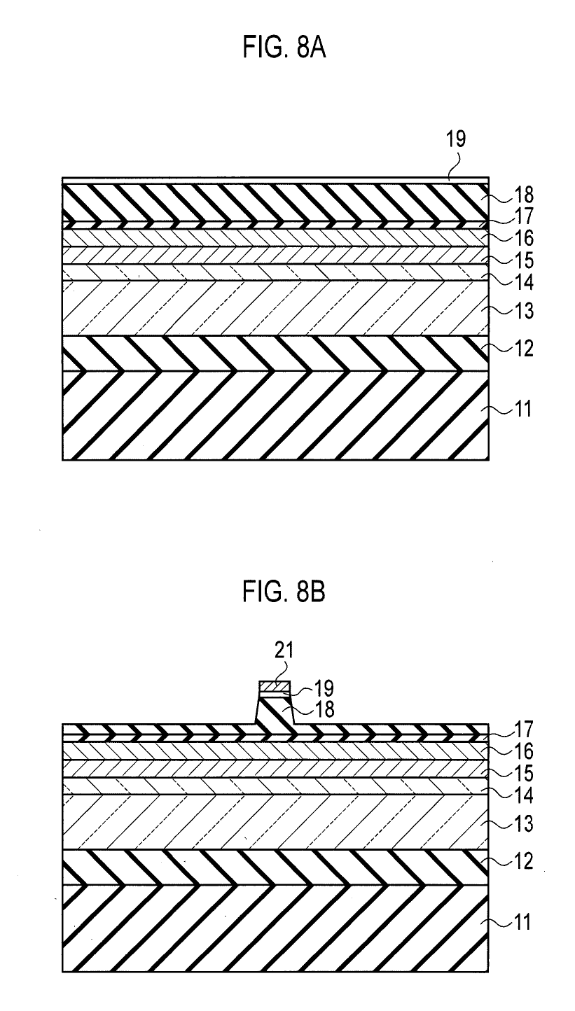

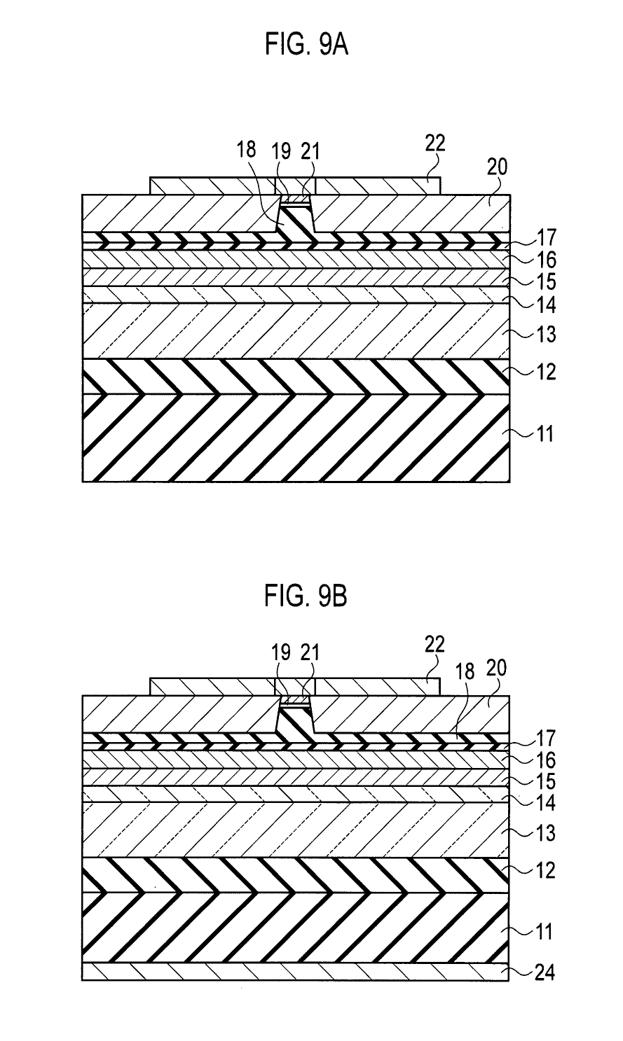

Next, a method of manufacturing a semiconductor laser element according to the first embodiment will be described using FIGS. 8A to 9B.

First, as shown in FIG. 8A, the buffer layer 12, which has a thickness of approximately 1 μm, and which is made of n-type GaN; the n-side cladding layer 13, which has a thickness of approximately 1.5 μm, and which is made of n-type Al_{0.05}Ga_{0.95}N; and the n-side optical guide layer 14, which has a thickness of approximately 50 nm, and which is made of undoped GaN, are sequentially grown on the n-type GaN substrate 11 at a substrate temperature of approximately 1150° C. by metal organic vapor phase epitaxy (MOVPE).

Then, three well layers 15b, each of which has a thickness of approximately 4 nm, and each of which is made of undoped In_{0.10}Ga_{0.90}N; and two barrier layers 15a, each of which has a thickness of approximately 15 nm, and each of which is made of undoped GaN, are alternately grown on the n-side optical guide layer 14 in a state in which the substrate temperature is maintained at approximately 850° C., thus forming the active layer 15. Subsequently, the p-side optical guide layer 16, which has a thickness of approximately 100 nm, and which is made of undoped GaN; and the cap layer 17, which has a thickness of approximately 20 nm, and which is made of undoped Al_{0.30}Ga_{0.70}N, are sequentially grown on the active layer 15. This cap layer 17 has the function of preventing In atoms from leaving the active layer 15 and thereby preventing the crystal quality of the active layer 15 from deteriorating.

Thereafter, the p-side cladding layer 18, which has a thickness of approximately 500 nm, and which is made of p-type Al_{0.05}Ga_{0.95}N, is grown on the cap layer 17 in a state in which the substrate temperature is set at approximately 1150° C.

Then, the p-side contact layer 19, which has a thickness of approximately 10 nm, and which is made of undoped In_{0.05}Ga_{0.95}N, is grown on the p-side cladding layer 18 in a state in which the substrate temperature is maintained at approximately 850° C.

Next, as shown in FIG. 8B, a Pt/Pd film is formed on the p-side contact layer 19 by vacuum evaporation, and is then etched using a photoresist, thereby forming the stripe-shaped p-side electrode 21, which has a width of approximately 1.5 μm. Moreover, the p-side contact layer 19 and the p-side cladding layer 18 are partially removed by etching, thereby forming a ridge portion which serves as a current injection region.

Subsequently, as shown in FIG. 9A, the current blocking layer 20, which has a thickness of approximately 300 nm, and which is made of a SiO₂ film, is formed by plasma CVD in a manner covering the top of the p-side electrode 21, side surfaces of the p-side contact layer 19 and the p-side cladding layer 18, and the flat portions of the p-side cladding layer 18.

Thereafter, using a photoresist having an opening portion corresponding to the ridge portion, the current blocking layer 20 directly above the p-side electrode 21 is etched to expose the p-side electrode 21. Next, using a photoresist, the comb-shaped p-side pad electrode 22 made of Ti/Au is formed on the p-side electrode 21 and the current blocking layer 20 by vacuum evaporation using a lift-off technique. In this case, since Ti is used for the lowest layer of the p-side pad electrode 22, it is possible to improve adhesion of the p-side pad electrode 22 to the current blocking layer 20 made of SiO₂.

Next, as shown in FIG. 9B, the n-type GaN substrate 11 is thinned to a thickness of, for example, approximately 100 μm by grinding the back surface of the n-type GaN substrate 11, and then the n-side electrode 24 made of Ti/Pt/Au is formed on the back surface thereof by vacuum evaporation.

Thereafter, cleavage is performed along such a direction that the light output facet becomes an M-plane surface in which a flat surface can be easily obtained, and breaking is performed in a direction orthogonal to the foregoing direction. Furthermore, the n-side electrode is connected to the conductive layer 26 by heat treatment at approximately 300° C. using the fusion layer 25 made of AuSn, and the wire 23 is bonded. Thereby, the semiconductor laser element shown in FIGS. 5 to 6B is manufactured.

(Effects and Advantages)

In the semiconductor laser element and the method of manufacturing a semiconductor laser element according to the first embodiment, a gap through which the current blocking layer 20 is exposed is provided between each adjacent two of the plurality of protruding portions 22b provided in the p-side pad electrode 22. Accordingly, assuming that the total area where the electrodes are formed is equivalent, the region in which wire bonding can be performed becomes wider than that for the case where no gap is provided between each adjacent two of the plurality of protruding portions 22b, i.e., the case where the protruding portions are gathered into one. Moreover, the area in which the p-side pad electrode 22 is formed, i.e., the area in which capacitance occurs, can be reduced compared to that for the case where the p-side pad electrode is formed over the entire surface of the semiconductor laser element. Accordingly, parasitic capacitance is reduced, and the semiconductor laser element can operate at high frequency.

Accordingly, an expansion of the region in which wire bonding can be performed and a decrease in the area in which capacitance occurs allow the semiconductor laser element to operate at high frequency, and concurrently make it possible to reduce failures occurring at the time of wire bonding. As a result, a decrease in fabrication yield can be prevented.

The protruding portions 22b of the p-side pad electrode 22 are placed at regular intervals along the direction (direction A shown in FIG. 5) in which the ridge portion extends, and the p-side pad electrode 22 has a comb-like shape in which the end portions of the protruding portions 22b in the width direction (direction B shown in FIG. 5) of the ridge portion are not continuous with one another. Accordingly, gaps can be easily provided, and parasitic capacitance can be reduced. Moreover, the protruding portions 22b of the comb-shaped p-side pad electrode 22 made of a material having a high thermal conductivity can be made to function as radiating fins. Accordingly, heat generated by light absorption in the operation of the semiconductor laser element and Joule heat due to electric resistance can be efficiently dissipated into the outside environment. As a result, deterioration in semiconductor laser element characteristics can be prevented.

Moreover, when the conductive layer width of the comb-shaped p-side pad electrode 22 is small, the adhesion strength between the current blocking layer 20 and the p-side pad electrode 22 becomes low, and delamination becomes prone to occur in a wire bonding step as shown in FIG. 7. However, by setting the width of each protruding portion 22b of the p-side pad electrode 22 at not less than 10 μm, the adhesion strength between the current blocking layer 20 and the p-side pad electrode 22 can be sufficiently ensured. As a result, a decrease in fabrication yield can be prevented.

Furthermore, in the semiconductor laser element according to the first embodiment, both the conductive layer width (width a shown in FIG. 5) of the comb-shaped p-side pad electrode 22 and the gap width thereof (width b shown in FIG. 5) are 15 μm. Accordingly, parasitic capacitance can be reduced to approximately 37% of that for the case where the p-side pad electrode is formed over the entire chip region (approximately 300 μm×400 μm), or approximately 55% of that for the case where the p-side pad electrode is formed over the entire effective wire bonding region (200 μm×400 μm), in consideration of parasitic capacitance occurring directly under the bonding wire 23. Accordingly, the operating speed of the semiconductor laser element can be increased.

In addition, the width a of each protruding portion 22b of the p-side pad electrode 22 is not more than the width b of each gap. This reduces the value of parasitic capacitance to approximately half or less of that for the case where the conductive layer is formed over the entire surface. As a result, high-speed operation can be achieved.

In addition, the period d of the comb-shaped p-side pad electrode 22 is 30 μm, equivalent to ½ or less of 70 μm, which is the bond diameter of the bonding wire 23. Accordingly, the bonding wire 23 can be bonded to three or more protruding portions of the comb-shaped p-side pad electrode 22, and the bonding wire 23 can be prevented from peeling off. Since the adhesion strength between the p-side pad electrode 22 and the bonding wire 23 can be sufficiently ensured as described above, a decrease in fabrication yield can be prevented.

Moreover, in the semiconductor laser element according to the first embodiment, the p-side pad electrode 22 contains titanium. Since titanium has strong adhesion to oxide materials, adhesion of the p-side pad electrode 22 to the current blocking layer 20 made of SiO₂ improves. This makes it possible to make delamination less prone to occur in spite of the comb-like shape. As a result, a decrease in fabrication yield can be prevented.

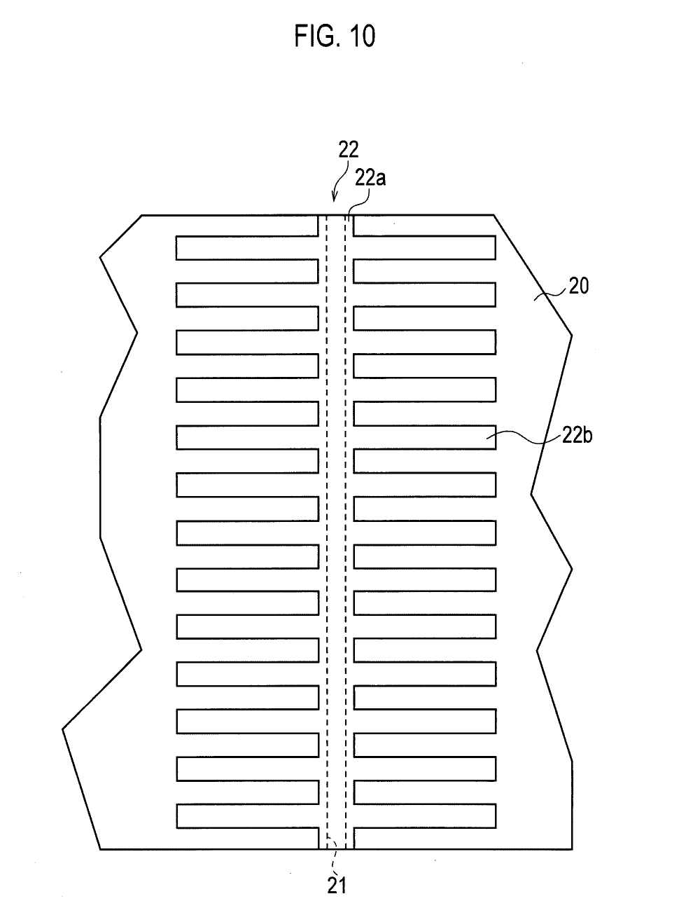

Furthermore, the semiconductor laser element according to the first embodiment includes a GaN substrate and a nitride semiconductor layer having a hexagonal crystal structure. In addition, the laser light output facet is an M-plane surface. In a nitride semiconductor layer containing GaN, since a flat surface is difficult to obtain in a direction orthogonal to the M-plane surface, irregularities in side surfaces of the chip become significant, for example, as shown in FIG. 10, or failures such as the occurrence of chipping at an edge are prone to occur. Accordingly, in the case where a wire bonding position is determined by recognizing an image of the outer shape, pattern recognition cannot be normally performed, and accurate alignment becomes difficult. However, since the p-side pad electrode 22 is formed in a wide region, power can be normally supplied even if the wire bonding position is displaced. As a result, a decrease in fabrication yield can be prevented.

### MODIFIED EXAMPLES

In the p-side pad electrode 22 according to the above-described first embodiment, the protruding portions 22b are provided on both sides of the straight portion 22a, and provided over almost the entire surface of the semiconductor laser element. However, the present invention is not limited to this. Specifically, the region in which the protruding portions 22b are formed can also be reduced according to characteristics (alignment accuracy and a direction in which “displacement” is expected to occur) which are intrinsic to a wire bonder, in a range in which a failure does not occur in wire bonding.

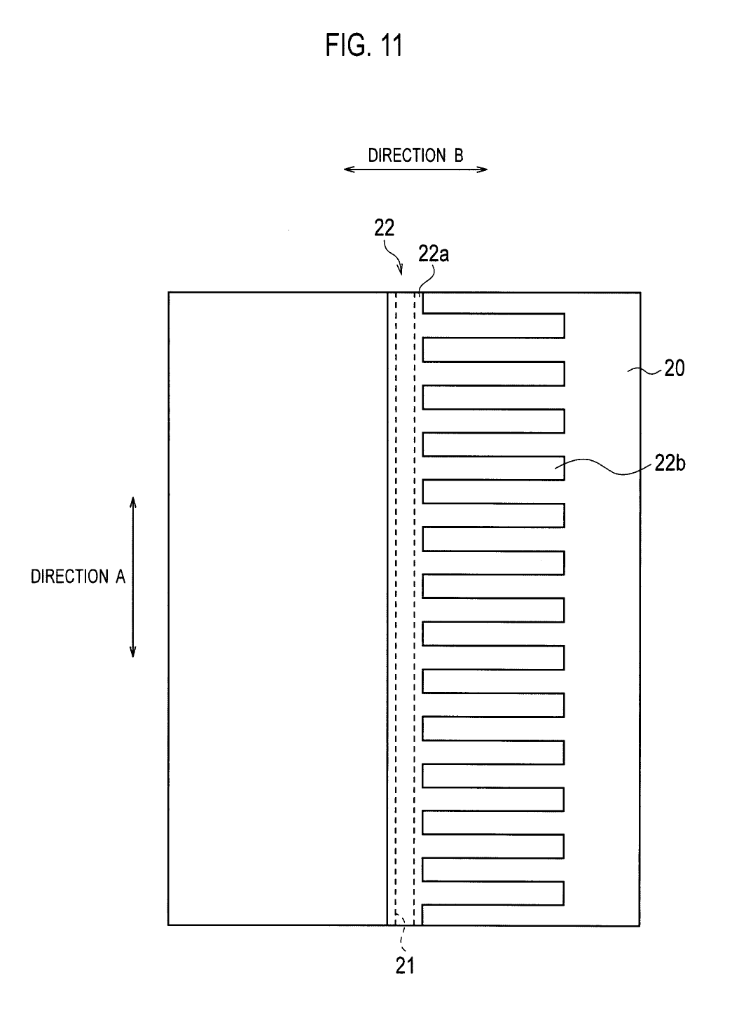

For example, consideration will be given to the case where it is expected that displacement in alignment will occur only in the direction (direction A shown in FIG. 5) in which a resonator (ridge portion and straight portion 22a) extends. In such a case, the lengths of the protruding portions 22b can be shortened in the width direction (direction B shown in FIG. 5) of the resonator (ridge portion and straight portion 22a). Alternatively, as shown in FIG. 11, it is also possible to provide the protruding portions 22b only on one side of the straight portion 22a (ridge portion).

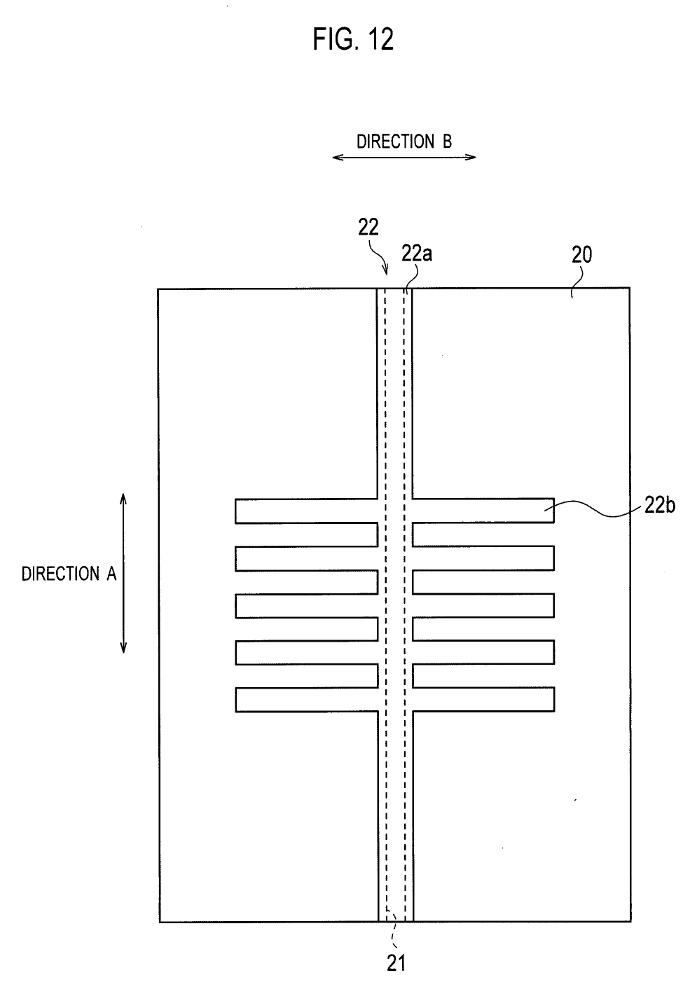

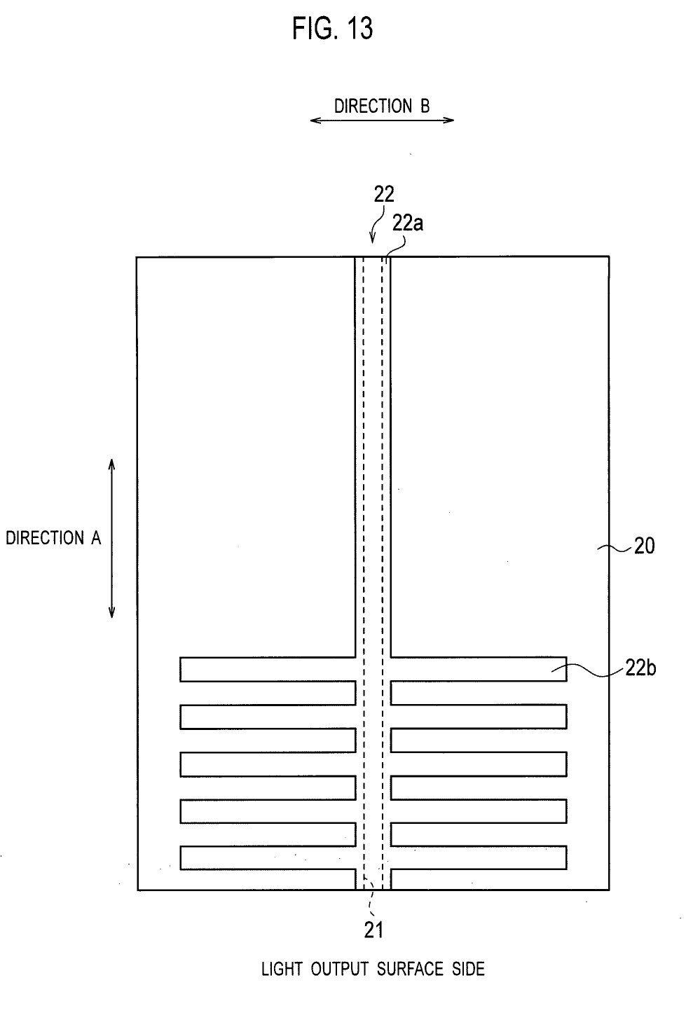

Next, consideration will be given to the case where it is expected that displacement in alignment will occur only in the width direction (direction B shown in FIG. 5) of the resonator (ridge portion and straight portion 22a). In such a case, as shown in FIGS. 12 and 13, the region in which the protruding portions 22b are provided can also be narrowed in the direction (direction A shown in FIG. 5) in which the resonator (ridge portion and straight portion 22a) extends.

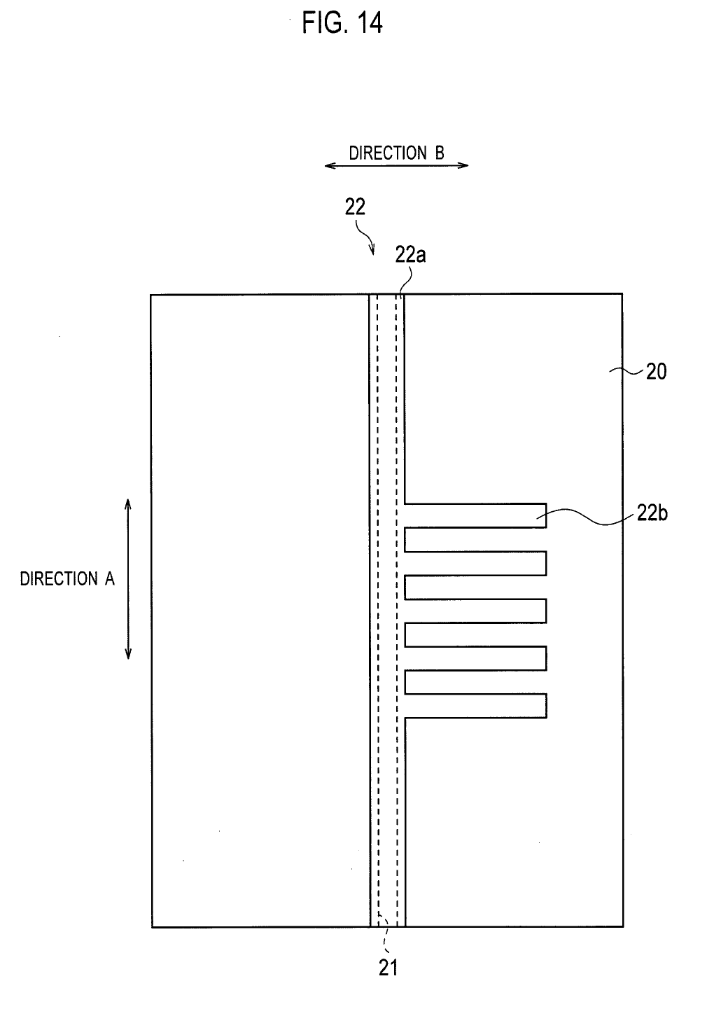

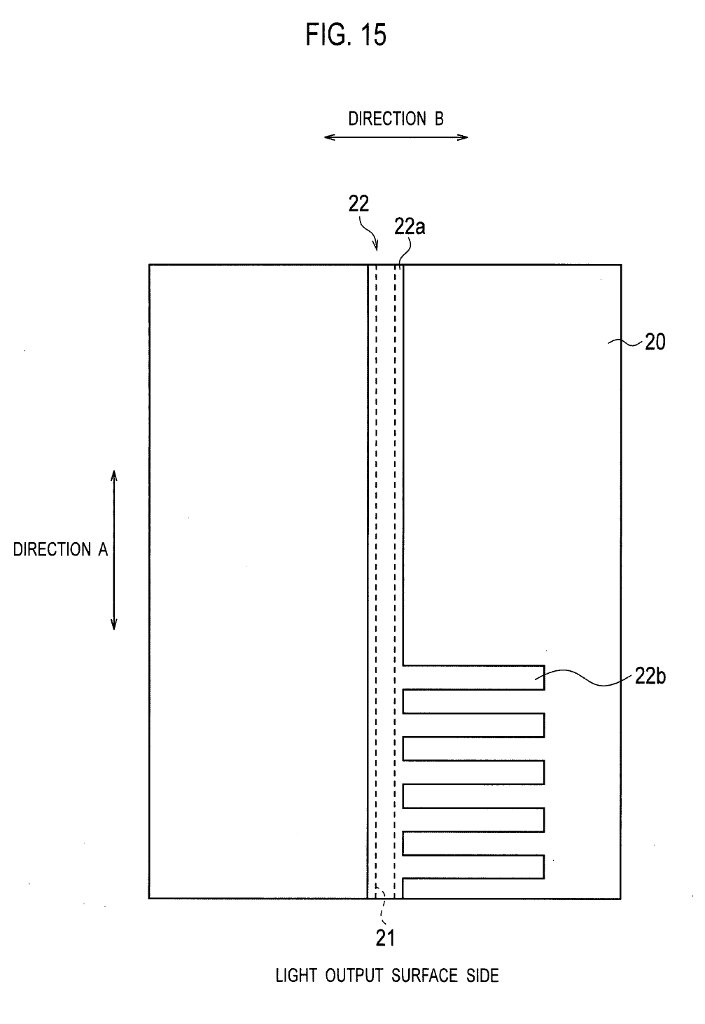

Finally, consideration will be given to the case where it is expected that there will be not much displacement in alignment in the direction (direction A shown in FIG. 5) in which the resonator (ridge portion and straight portion 22a) extends and in the width direction (direction B shown in FIG. 5) of the resonator (ridge portion and straight portion 22a). In such a case, as shown in FIGS. 14 and 15, the protruding portions 22b can be provided only on one side of the straight portion 22a (ridge portion), and the region in which the protruding portions 22b are provided can also be narrowed in direction A.

By narrowing the region on the surface of the semiconductor laser element in which the protruding portions 22b are provided as shown in FIGS. 11 to 15, parasitic capacitance can be further reduced.

By providing the protruding portions 22b on a side close to the light output facet, which is prone to be broken due to a thermal factor associated with light absorption, as shown in FIGS. 13 and 15, parasitic capacitance can be reduced without decreasing the efficiency of heat dissipation to a large extent.

Moreover, as shown in FIG. 16, in order to ensure the contact area of a wire when the wire is bonded to an end of the chip, the p-side pad electrode 22 may have a shape in which the end portions of each adjacent two of the protruding portions 22b on outer sides in the width direction b of the straight portion 22a (ridge portion) are connected to each other by a portion 22c. In the pattern of FIG. 16, since the p-side pad electrode 22 has a shape in which the end portions of the protruding portions 22b are continuous with one another, adhesion of the p-side pad electrode 22 to the wire is improved compared to that of the comb-shaped p-side pad electrode shown in FIG. 5.

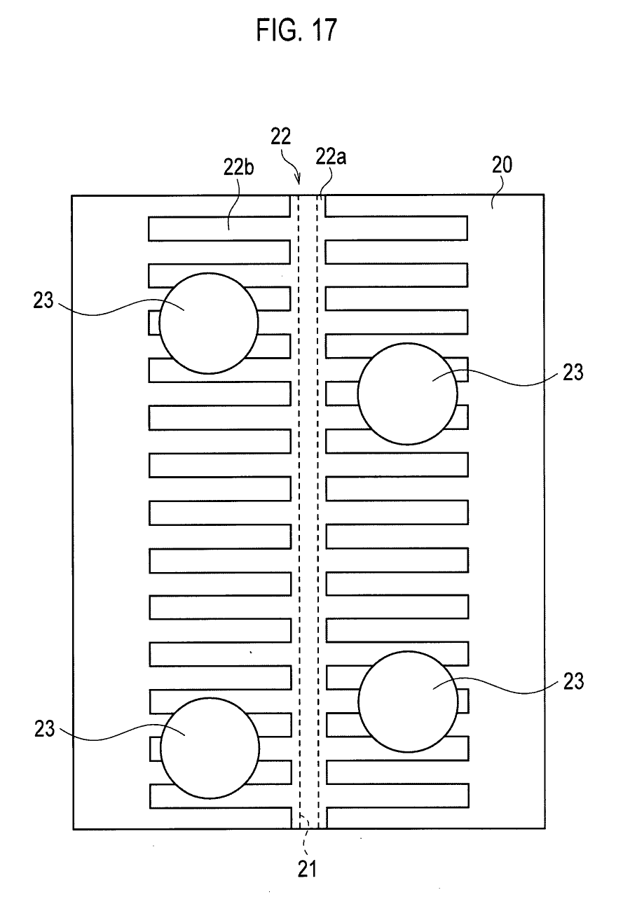

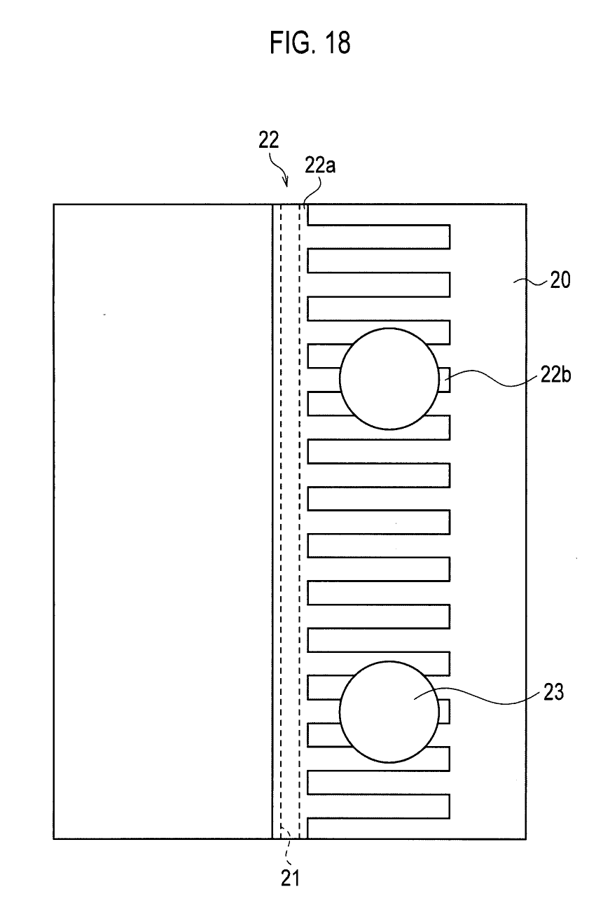

In the aforementioned first embodiment, the number of wires bonded to the p-side pad electrode 22 is one. However, the present invention is not limited to this. Specifically, as shown in FIGS. 17 and 18, a plurality of wires may be bonded to the p-side pad electrode 22. This makes it possible to supply a large current while reducing parasitic capacitance. As a result, the operating speed of the semiconductor laser element can be increased.

### Second Embodiment

(Structure of Semiconductor Laser Element)

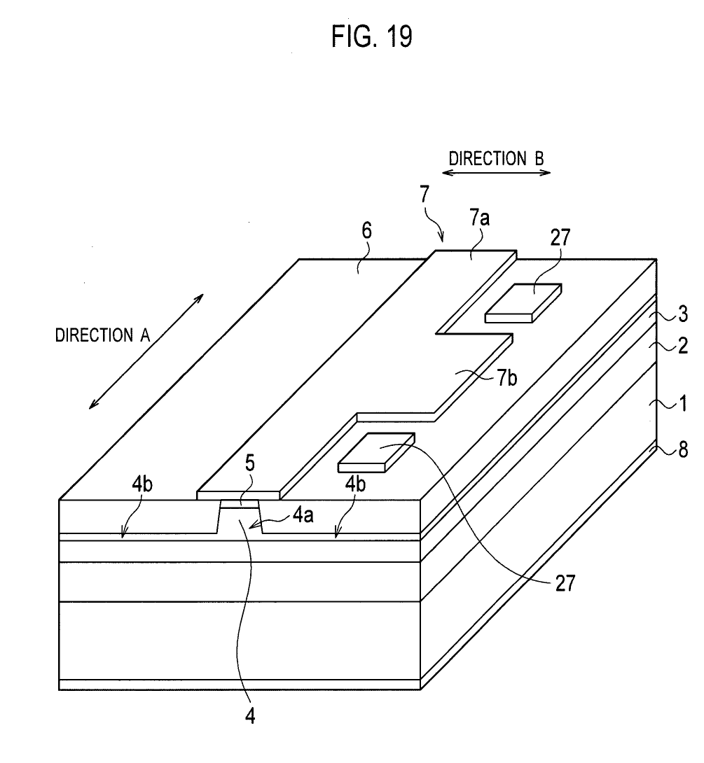

The schematic structure of a semiconductor laser element according to a second embodiment will be described using FIG. 19. The semiconductor laser element includes a semiconductor layer including: a first cladding layer 2 of a first conductivity type formed on a substrate 1; an active layer 3 formed on the first cladding layer 2; a second cladding layer 4 of a second conductivity type provided on the active layer 3; and a contact layer 5 provided on a raised portion 4a of the second cladding layer 4. The second cladding layer 4 includes the raised portion 4a extending in direction A, and flat portions 4b provided on outer sides in the width direction (direction B) of the raised portion 4a.

The semiconductor laser element includes a current blocking layer 6, which is formed on the upper surfaces of the flat portions 4b and side surfaces of the raised portion 4a, and which is made of an insulating material. The semiconductor laser element further includes an electrode 7 formed on the contact layer 5 and the current blocking layer 6.

The electrode 7 includes a straight portion 7a provided along direction A on the contact layer 5 (over the raised portion 4a), and a protruding portion 7b protruding outward from the straight portion 7a in the width direction (direction B) of the raised portion 4a. On the current blocking layer 6, island-shaped bonding portions 27 are provided which are not in contact with the electrode 7. Each of the bonding portions 27 is adjacent to the protruding portion 7b. It should be noted that a gap through which the current blocking layer 6 is exposed is provided between the protruding portion 7b and each of the bonding portions 27. The width of each gap is preferably not more than ½ of the bond diameter of a bonding wire as in the first embodiment.

(Structure of Semiconductor Laser Element)

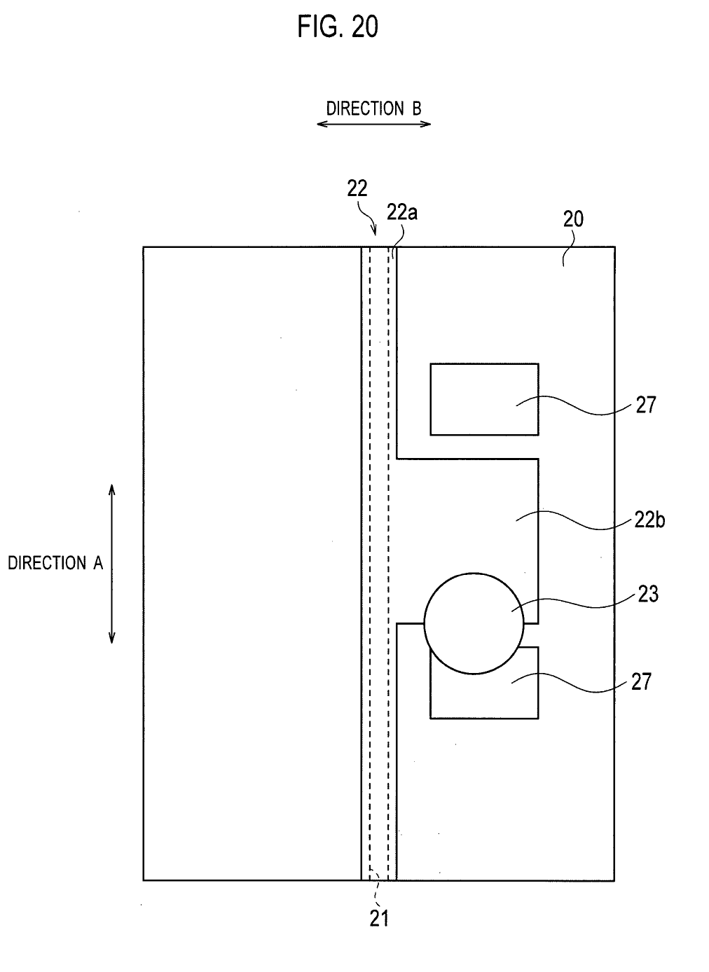

Next, the structure of the semiconductor laser element according to the second embodiment will be described in detail. FIG. 20 is a top view showing the structure of a 400-nm-wavelength semiconductor laser element (violet LD) which is made of a nitride semiconductor and in which a GaN substrate is used. The detailed structure of the semiconductor laser element according to the second embodiment is similar to that of the first embodiment, except for the provision of the island-shaped bonding portions 27. Accordingly, portions other than the bonding portions 27 will not be further described.

A bonding wire 23 made of Au is connected to a portion of the p-side pad electrode 22, and thereby the p-side pad electrode 22 can be supplied with power from an external power supply. The bonding wire 23 is also connected to the bonding portion 27. Accordingly, the adhesion strength between the p-side pad electrode 22 and the bonding wire 23 is sufficiently ensured.

The bonding portions 27 may be made of any material having strong adhesion. For example, titanium, chromium, or aluminum is used.

(Effects and Advantages)

In the semiconductor laser element according to the second embodiment, the island-shaped bonding portions 27, which are not in contact with the p-side pad electrode 22, are provided on the current blocking layer 20, and each of the bonding portions 27 is adjacent to the protruding portion 22b. In addition, a gap through which the current blocking layer 20 is exposed is provided between the protruding portion 22b and each of the bonding portions 27. Accordingly, the region in which wire bonding can be performed becomes wider than that for the case where only one protruding portion is provided. Moreover, the area in which the electrode is formed, i.e., the area in which capacitance occurs, can be reduced compared to that for the case where the electrode is formed over the entire surface of the semiconductor laser element. As a result, parasitic capacitance is reduced, and the semiconductor laser element can operate at high frequency.

Accordingly, an expansion of the region in which wire bonding can be performed and a decrease in the area in which capacitance occurs allow the semiconductor laser element to operate at high frequency, and make it possible to reduce failures occurring at the time of bonding a wire for supplying power.

### Modified Examples

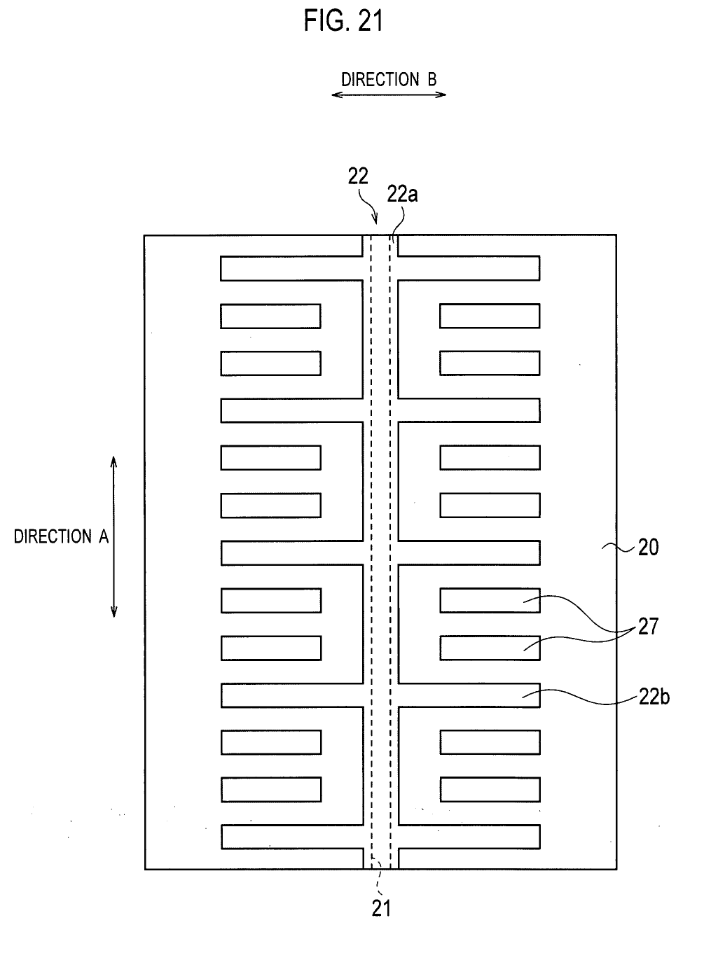

In the second embodiment, a semiconductor laser element including the island-shaped bonding portions 27 has been described. The island-shaped bonding portions 27 may be used in combination with the comb-shaped p-side pad electrode 22 described in the first embodiment. For example, as shown in FIG. 21, island-shaped bonding portions 27 may be placed in gaps of the comb-shaped p-side pad electrode 22. Such a structure can further improve adhesion.

### Third Embodiment

(Structure of Semiconductor Laser Element)

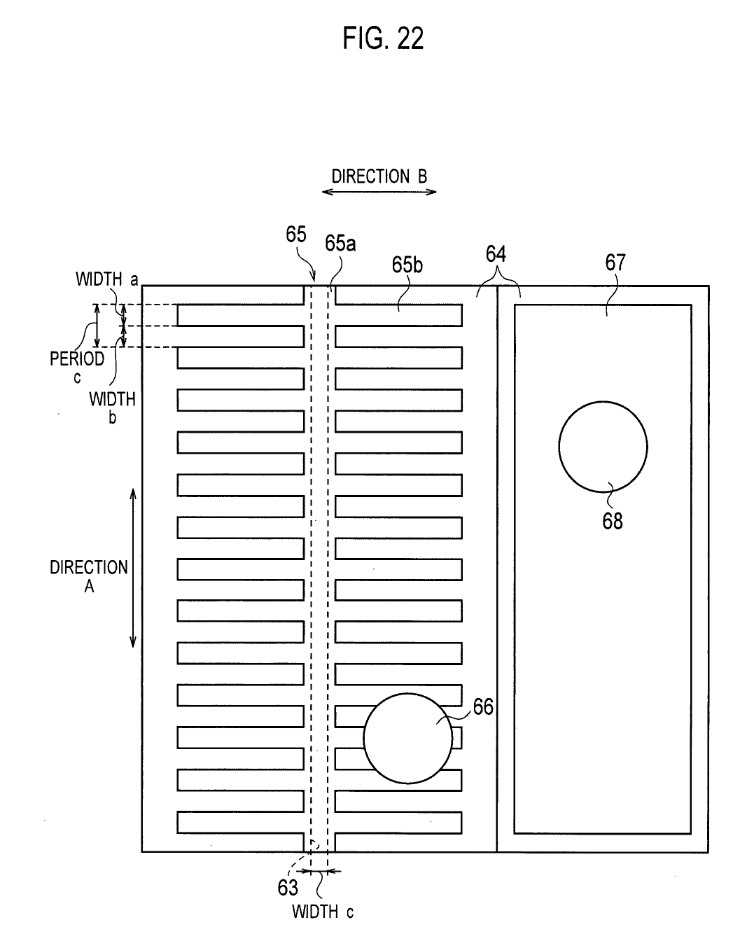

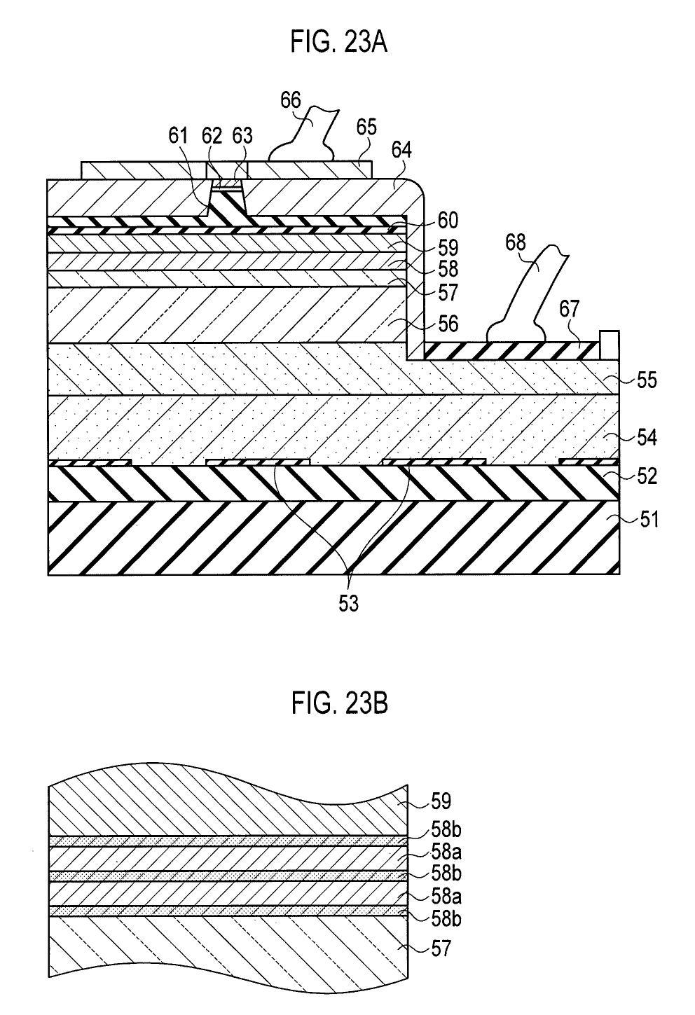

Next, the structure of a semiconductor laser element according to a third embodiment will be described using FIGS. 22 to 23B. FIG. 22 is a top view showing the structure of a 400-nm-wavelength semiconductor laser element (violet LD) which is made of a nitride semiconductor and in which an insulating sapphire substrate is used. FIGS. 23A and 23B are cross-sectional views showing the same.

As shown in FIG. 23A, on a sapphire substrate 51 having a c-plane surface ((0,0,0,1) surface), a buffer layer 52 is formed, which has a thickness of approximately 10 μm, and which is made of an undoped GaN layer. On this buffer layer 52, a SiO₂ layer 53 is formed, which has a thickness of approximately 100 nm and the shape of stripes. Each of the stripes has a width of approximately 6 μm, and extends in the direction orthogonal to the plane of the drawing. In addition, each adjacent two of the stripes are spaced approximately 4 μm apart. A laterally grown layer 54, which has a thickness of approximately 12 μm, and which is made of an undoped GaN layer, is formed to surround the SiO₂ layer 53. Moreover, on the laterally grown layer 54, an n-side contact layer 55 is formed, which has a thickness of approximately 1 μm and a raised portion, and which is made of Si-doped n-type GaN. On a flat portion of this n-side contact layer 55, an n-side electrode 67 is formed, which is made of Ti/Pt/Au (10 nm/2 nm/500 nm).

On the other hand, on the raised portion of the n-side contact layer 55, an n-side cladding layer 56 is formed, which has a thickness of approximately 1.5 μm, and which is made of Si-doped n-type Al_{0.05}Ga_{0.95}N. On the n-side cladding layer 56, an n-side optical guide layer 57 is formed, which has a thickness of approximately 50 nm, and which is made of undoped GaN. Furthermore, on the n-side optical guide layer 57, an active layer 58 is formed, which has a multiple quantum well (MQW) structure. As shown in FIG. 23B, this active layer 58 has a structure in which two barrier layers 58a and three well layers 58b are alternately laminated. Each barrier layer 58a has a thickness of approximately 15 nm, and is made of undoped GaN, and each well layer 58b has a thickness of approximately 4 nm, and is made of undoped In_{0.10}Ga_{0.90}N.

On the active layer 58, a p-side optical guide layer 59 is formed, which has a thickness of approximately 100 nm, and which is made of undoped GaN. On the p-side optical guide layer 59, a cap layer 60 is formed, which has a thickness of approximately 20 nm, and which is made of undoped Al_{0.30}Ga_{0.70}N.

On the cap layer 60 made of undoped Al_{0.30}Ga_{0.70}N, a p-side cladding layer 61 is formed, which is made of p-type Al_{0.05}Ga_{0.95}N, and which is doped with Mg. The p-side cladding layer 61 has a maximum thickness of approximately 500 nm, and has a stripe-shaped raised portion having a width of approximately 1.5 μm near the center thereof. On the raised portion, a p-side contact layer 62 is formed, which has a thickness of approximately 10 nm, and which is made of undoped In_{0.05}Ga_{0.95}N. The raised portion of the p-side cladding layer 61 and the p-side contact layer 62 form a ridge portion which serves as a current injection region.

A SiO₂ insulating layer 64, which has a thickness of approximately 300 nm, and which serves as a current blocking layer, is formed in a manner covering regions except the region directly above the p-side contact layer 62 and the region in which the n-side electrode 67 is formed. Moreover, a p-side electrode 63 made of Pt/Pd (2 nm/10 nm) is formed on the surface of the p-side contact layer 62, and a p-side pad electrode 65, which has a comb-like shape, and which is made of Ti/Au (10 nm/500 nm), is formed on the p-side electrode 63 and a portion of the insulating layer 64.

As shown in FIG. 22, the p-side pad electrode 65 includes a straight portion 65a provided along direction A on the p-side electrode 63 (over the raised portion of the p-side cladding layer 61), and a plurality of protruding portions 65b protruding outward from the straight portion 65a in direction B. Here, the straight portion 65a and the plurality of protruding portions 65b are example of “the first portion” and “the second portion” in the claims, respectively. A gap is provided between each adjacent two of the plurality of protruding portions 65b. A bonding wire 66 made of Au is connected to a portion of the p-side pad electrode 65, and a bonding wire 68 made of Au is connected to a portion of the n-side electrode 67, whereby the p-side pad electrode 65 and the n-side electrode 67 can be supplied with power from an external power supply.

In the third embodiment, the width a of each protruding portion 65b and the width b of each gap are equivalent, for example, approximately 15 μm. The width c of the current injection region (p-side electrode 63) is approximately 15 μm. The region in which the bonding wire 66 is in contact with the current blocking layer 64 and the p-side pad electrode 65 is an approximately circular region having a diameter of approximately 70 μm. Similarly, the region in which the bonding wire 68 is in contact with the n-side electrode 67 is an approximately circular region having a diameter of approximately 70 μm.

Moreover, the semiconductor laser element has a width of approximately 400 μm and a depth of approximately 400 μm. The region in which the layers from the n-side cladding layer 56 to the p-side cladding layer 61 are formed has a width of approximately 250 μm and a depth of approximately 400 μm. Furthermore, the surface (facet) from which laser light is emitted is an M-plane surface ({1,−1,0,0} surface).

(Method of Manufacturing Semiconductor Laser Element)

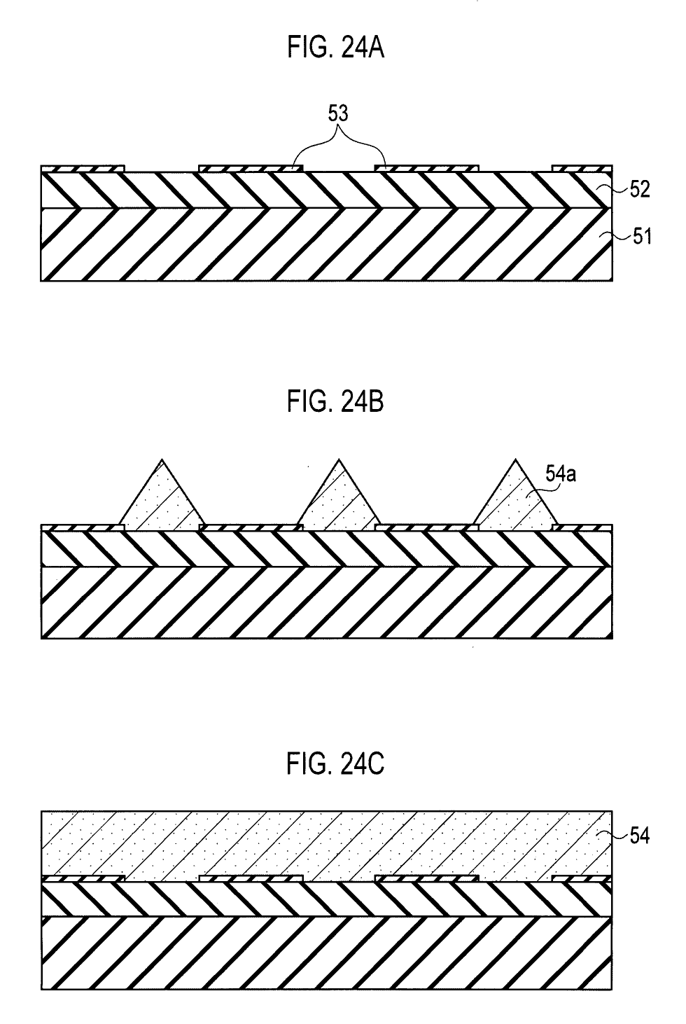

Next, a method of manufacturing a semiconductor laser element according to the third embodiment will be described using FIGS. 24A to 26B.

First, as shown in FIG. 24A, the buffer layer 52, which has a thickness of approximately 1 μm, and which is made of undoped GaN, is grown on the sapphire substrate 51, which has a c-plane surface, by two-step MOVPE growth (a low-temperature buffer layer grown at 600° C. and a layer grown at 1000° C.). A SiO₂ film having a thickness of approximately 100 nm is formed on the entire surface of the buffer layer 52 by plasma CVD. Then, a patterned photoresist is formed, and portions of the SiO₂ film are removed by etching, thereby forming the SiO₂ film 53, which has the shape of stripes, and which serves as a mask for selective growth. Each of the stripes has a width of approximately 6 μm, and each adjacent two of the stripes are spaced approximately 4 μm apart.

Then, an undoped GaN layer is grown on the buffer layer 52 and the SiO₂ film 53 by MOVPE at 1100° C. At this time, the undoped GaN layer does not easily grow on the SiO₂ film 53, and a GaN layer 54a having (1,2,−2,2) inclined surfaces and facet structures with triangular cross sections is formed only in regions in which the buffer layer 52 made of undoped GaN is exposed, as shown in FIG. 24B.

When the GaN layer is further grown, the GaN layer is also formed on the SiO₂ film 53 by lateral growth as shown in FIG. 24C. When the GaN layer is grown to a thickness of approximately 12 μm, the GaN layer having facet structures is integrated, and thereby the laterally grown layer 54 having a flat continuous upper surface is obtained. In this case, defects caused by differences in physical properties between the GaN layer and sapphire, which is the material of the substrate, are less prone to propagate to the laterally grown layer 54 on the SiO₂ film 53. For this reason, a good-quality GaN layer having low defect density can be obtained, except for portions in which the GaN layer is integrated.

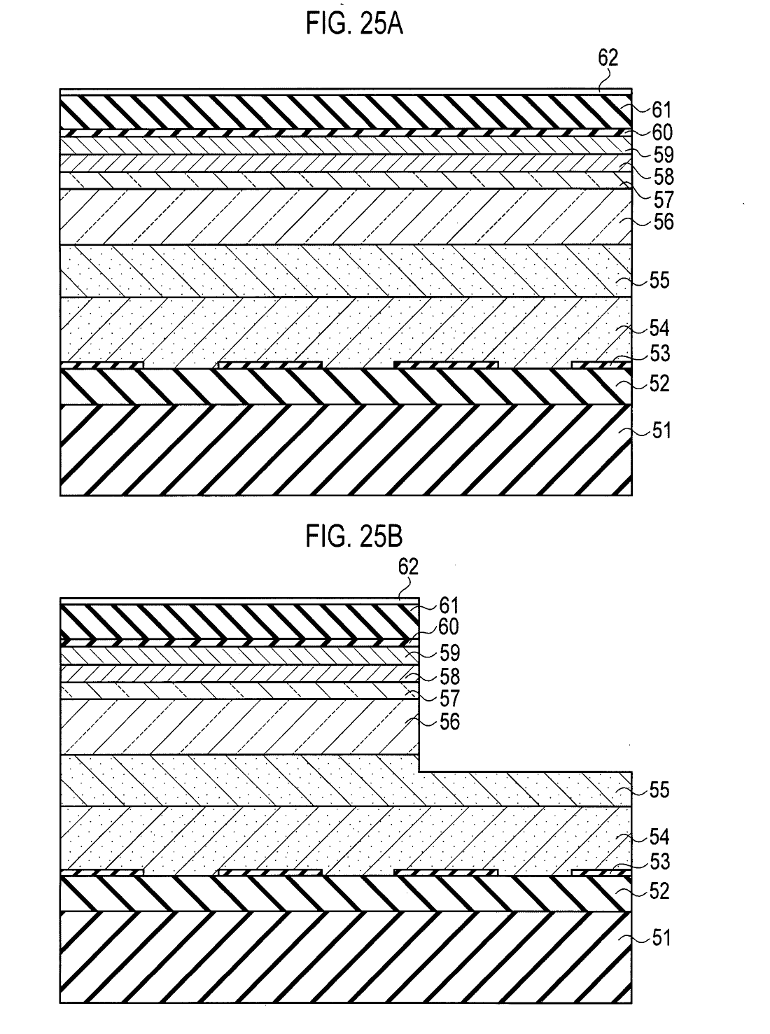

On this laterally grown layer 54, a semiconductor layer which serves as an operating layer of the semiconductor laser element is grown by MOVPE as shown in FIG. 25A. First, the n-side contact layer 55, which has a thickness of approximately 1 μm, and which is made of n-type GaN; the n-side cladding layer 56, which has a thickness of approximately 1.5 μm, and which is made of n-type Al_{0.05}Ga_{0.95}N; and the n-side optical guide layer 57, which has a thickness of approximately 50 nm, and which is made of undoped GaN, are sequentially grown at a substrate temperature of approximately 1150° C.

Then, three well layers 58b, each of which has a thickness of approximately 4 nm, and each of which is made of undoped In_{0.10}Ga_{0.90}N; and two barrier layers 58a, each of which has a thickness of approximately 15 nm, and each of which is made of undoped GaN, are alternately grown on the n-side optical guide layer 57 in a state in which the substrate temperature is maintained at approximately 850° C. Thereby the active layer 58 having an MQW structure is formed. Subsequently, the p-side optical guide layer 59, which has a thickness of approximately 100 nm, and which is made of undoped GaN; and the cap layer 60, which has a thickness of approximately 20 nm, and which is made of undoped Al_{0.30}Ga_{0.70}N, are sequentially grown on the active layer 58. This cap layer 60 has the function of preventing In atoms from leaving the MQW active layer 58 and thereby preventing the crystal quality of the active layer 58 from deteriorating.

Thereafter, the p-side cladding layer 61, which has a thickness of approximately 500 nm, and which is made of p-type Al_{0.05}Ga_{0.95}N, is grown on the cap layer 60 in a state in which the substrate temperature is set at approximately 1150° C.

Then, the p-side contact layer 62, which has a thickness of approximately 10 nm, and which is made of undoped In_{0.05}Ga_{0.95}N, is formed on the p-side cladding layer 61 in a state in which the substrate temperature is maintained at approximately 850° C.

Next, as shown in FIG. 25B, using a photoresist, a partial region is removed by etching to expose the n-side contact layer 55.

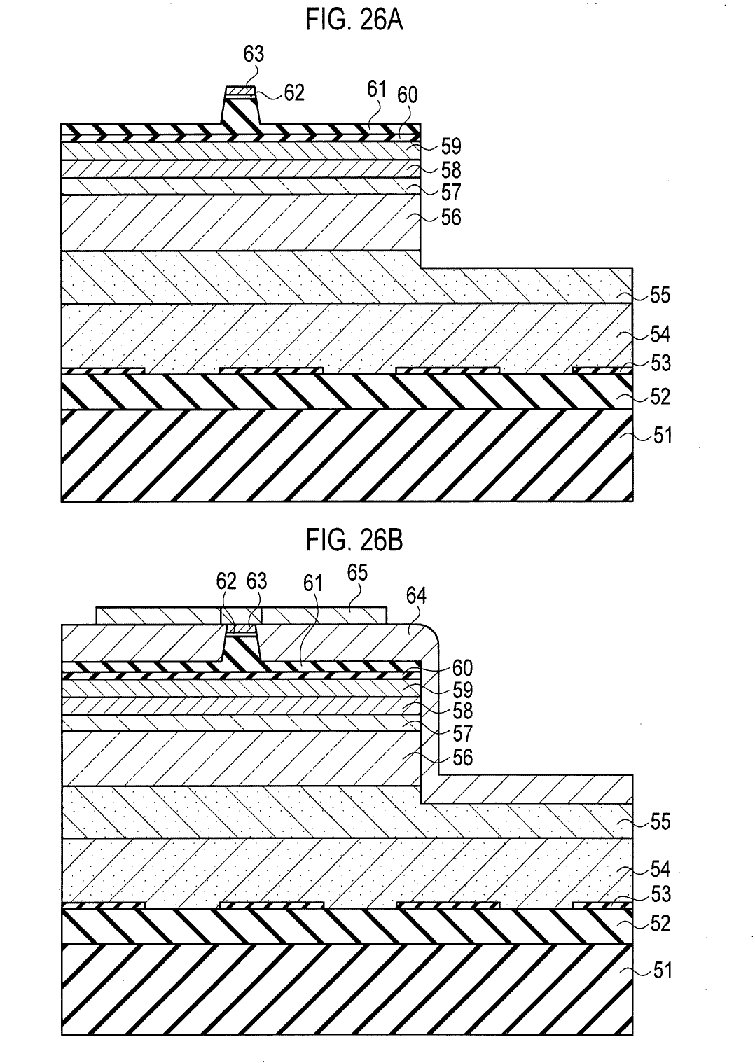

Thereafter, as shown in FIG. 26A, a Pt/Pd film is formed on the p-side contact layer 62 by vacuum evaporation, and is etched using a photoresist. Thereby, the stripe-shaped p-side electrode 63 which has a width of approximately 1.5 μm is formed. Furthermore, the p-side contact layer 62 and the p-side cladding layer 61 are partially removed by etching, and thereby a ridge portion which serves as a current injection region is formed.

Subsequently, as shown in FIG. 26B, the insulating layer 64, which has a thickness of approximately 300 nm, and which is made of a SiO₂ film, is formed by plasma CVD in a manner covering the entire semiconductor layer exposed.

Thereafter, using a photoresist having an opening portion corresponding to the ridge portion, the insulating layer 64 on the p-side electrode 63 is etched to expose the p-side electrode 63. Next, the comb-shaped p-side pad electrode 65 made of Ti/Au is formed on the p-side electrode 63 and the insulating layer 64 by vacuum evaporation. In this case, since Ti is used for the lowest layer of the p-side pad electrode 65, it is possible to improve adhesion of the p-side pad electrode 65 to the insulating layer 64 made of SiO₂.

Next, using a photoresist, the insulating layer 64 on the n-side contact layer 55 is partially removed by etching to expose the n-side contact layer 55, and then the n-side electrode 67 made of Ti/Pt/Au is formed by vacuum evaporation using a lift-off technique.

Next, the sapphire substrate 51 is thinned to a thickness of, for example, approximately 150 μm by grinding the back surface thereof so that cleavage is easily performed. Then, cleavage is performed along such a direction that the light output facet becomes an M-plane surface in which a flat surface can be easily obtained, and breaking is performed in a direction orthogonal to the foregoing direction. After the resulting structure is packaged in a predetermined package, and the wires 66 and 68 are bonded to the p-side pad electrode 65 and the n-side electrode 67, respectively. As a result, the semiconductor laser element shown in FIGS. 22A to 23B is manufactured.

(Effects and Advantages)

In the case of the semiconductor laser element according to the third embodiment, parasitic capacitance occurring in the insulating layer 64, which functions as a current blocking layer, can be reduced to approximately 44% of that for the case where the p-side pad electrode is formed over the entire region (approximately 250 μm×400 μm) in which the p-side cladding layer 61 is formed, or approximately 55% of that for the case where the p-side pad electrode is formed over the entire effective wire bonding region (approximately 200 μm×400 μm), in consideration of parasitic capacitance occurring directly under the bonding wire 66. Accordingly, the operating speed of the semiconductor laser element can be increased.

In addition, the semiconductor laser element according to the third embodiment includes a sapphire substrate and a nitride semiconductor layer having a hexagonal crystal structure. Moreover, the laser light output facet is an M-plane surface. In a nitride semiconductor layer containing GaN, since a flat surface is difficult to obtain in a direction orthogonal to the M-plane surface, irregularities in side surfaces of the chip become significant, for example, as shown in FIG. 10, or failures such as the occurrence of chipping at an edge are prone to occur. Accordingly, in a case where a wire bonding position is determined by recognizing an image of the outer shape, pattern recognition cannot be normally performed, and accurate alignment becomes difficult. However, since the p-side pad electrode 65 is formed in a wide region, power can be normally supplied even if the wire bonding position is displaced. As a result, a decrease in fabrication yield can be prevented.

### Fourth Embodiment

Hereinafter, a fourth embodiment will be described with reference to the accompanying drawings. In the fourth embodiment, a semiconductor laser device using the semiconductor laser element described in the first embodiment will be described.

(Structure of Semiconductor Laser Device)

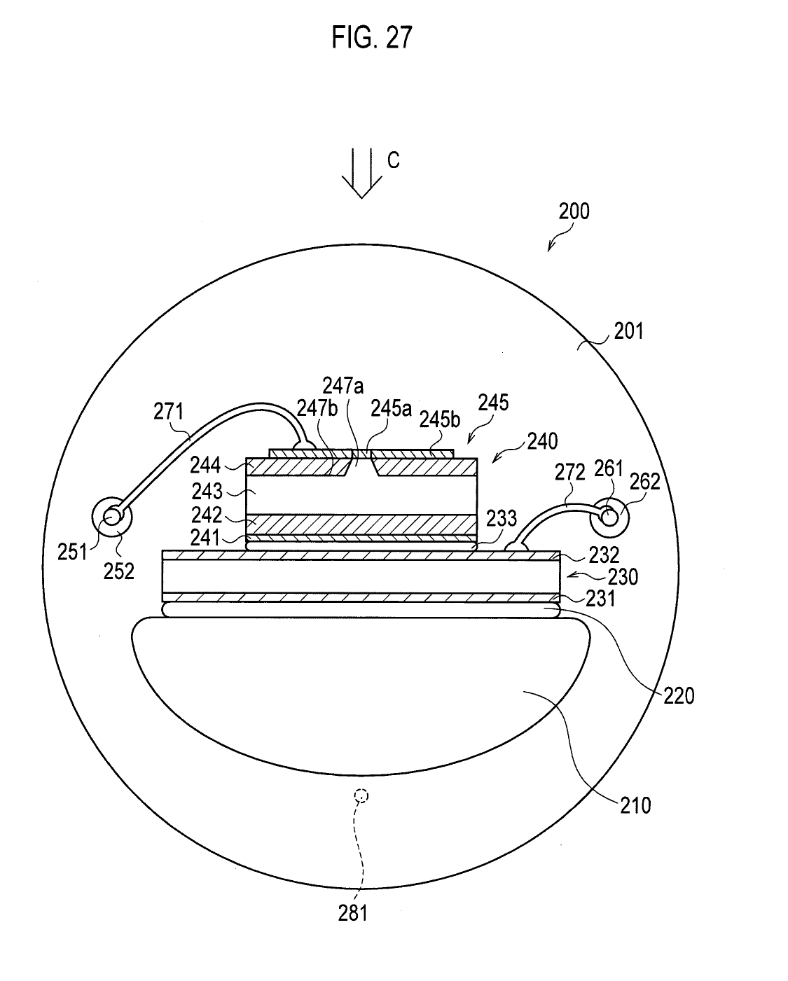

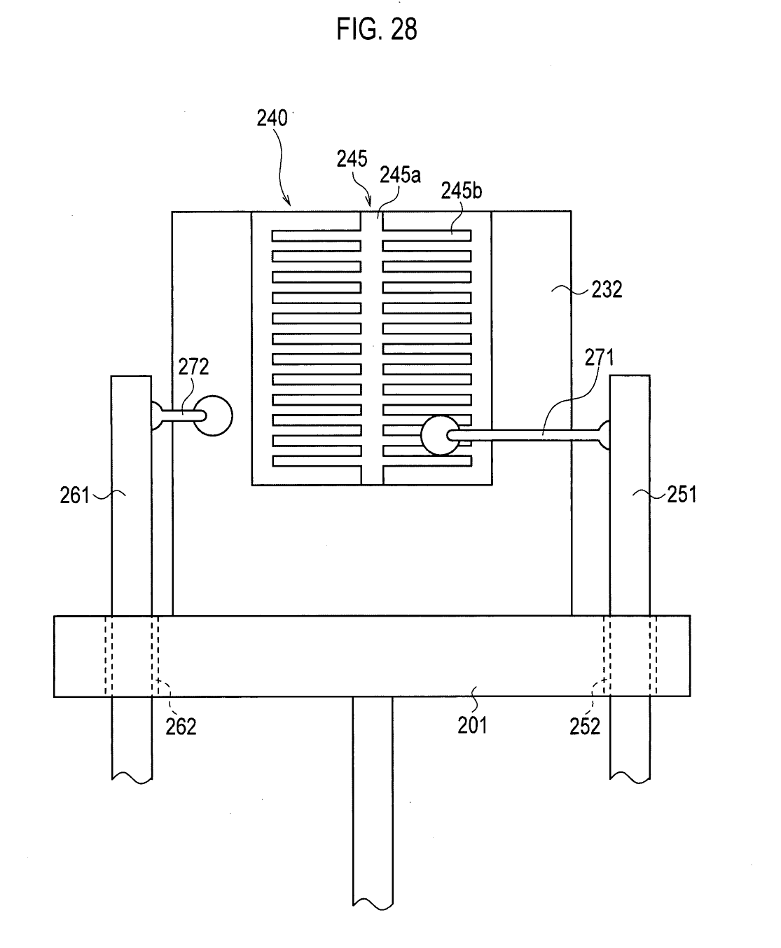

Hereinafter, the structure of a semiconductor laser device according to the fourth embodiment will be described with reference to the accompanying drawings. FIGS. 27 and 28 are views showing the structure of a semiconductor laser device 200 according to the fourth embodiment. Specifically, FIG. 27 is a view of the semiconductor laser device 200 seen from a light output facet side, and FIG. 28 is a view of the semiconductor laser device 200 seen in direction C shown in FIG. 27.

As shown in FIG. 27, the semiconductor laser device 200 includes a supporting base 210, a subsidiary substrate 230 mounted on the supporting base 210 with a fusion layer 220 interposed therebetween, and a semiconductor laser element 240 mounted on the subsidiary substrate 230 with a fusion layer 233 interposed therebetween. The subsidiary substrate 230 includes a pair of conductive layers (conductive layers 231 and 232). It should be noted that the conductive layer 232 corresponds to the aforementioned conductive layer 26, and that the fusion layer 233 corresponds to the aforementioned fusion layer 25.

The semiconductor laser device 200 includes power supply pins (power supply pins 251, 261, and 281) for connecting to an external power supply. The power supply pin 251 is inserted in an insulating ring 252 provided in a package body 201. Similarly, the power supply pin 261 is inserted in an insulating ring 262 provided in the package body 201.

The semiconductor laser element 240 includes an n-side electrode 241, a substrate 242, a semiconductor layer 243, a current blocking layer 244, and p-side pad electrode 245.

The n-side electrode 241 corresponds to the aforementioned n-side electrode 24, and the substrate 242 corresponds to the aforementioned substrate 11.

The semiconductor layer 243 includes the buffer layer 12, the n-side cladding layer 13, the n-side optical guide layer 14, the active layer 15, the p-side optical guide layer 16, the cap layer 17, the p-side cladding layer 18, and the p-side contact layer 19, which have been described previously. It should be noted that an electrode (not shown) corresponding to the aforementioned p-side electrode 21 is provided on the p-side contact layer 19.

The semiconductor layer 243 has a raised portion 247a, which is a current injection region, and flat portions 247b provided on outer sides in the width direction of the raised portion 247a, as in the aforementioned embodiments.

The current blocking layer 244 corresponds to the aforementioned current blocking layer 20, and is formed on side surfaces of the raised portion 247a and the upper surfaces of the flat portions 247b.

As shown in FIG. 28, the p-side pad electrode 245 corresponds to the aforementioned p-side pad electrode 22; and includes a straight portion 245a provided on the raised portion 247a, and a plurality of protruding portions 245b protruding outward from the straight portion 245a in the width direction of the raised portion 247a. Here, the straight portion 245a and the plurality of protruding portions 245b are example of “the first portion” and “the second portion” in the claims, respectively.

The aforementioned power supply pin 251 is connected to some of the protruding portions 22b of the p-side pad electrode 22 through a bonding wire 271. On the other hand, the aforementioned power supply pin 261 is connected to the conductive layer 232 through a bonding wire 272.

(Effects and Advantages)

In the semiconductor laser device according to the fourth embodiment, as in the first embodiment, the region in which the bonding wire 271 can be bonded can be expanded, and the area in which parasitic capacitance occurs can be reduced. Accordingly, the semiconductor laser device can operate at high frequency, and failures occurring at the time of wire bonding can be reduced.

### Other Embodiments

Although the present invention has been described using the above-described embodiments, statements and drawings constituting part of the present disclosure should not be construed as limiting the present invention. Various alternate embodiments, examples, and operational techniques will become apparent to those skilled in the art from the present disclosure.

For example, in the aforementioned embodiments, a description has been given in which the crystal of each semiconductor layer is grown by MOVPE. However, the present invention is not limited to this, and the crystal of each semiconductor layer may be grown by MBE, HVPE, gas-source MBE, or the like. In addition, the crystal structure of each semiconductor may be a wurtzite structure or a zinc blende structure.

Moreover, in the aforementioned embodiments, a nitride semiconductor element layer including layers made of GaN, AlGaN, and InGaN is used. However, the present invention is not limited to this, and a nitride semiconductor element layer including layers made of AlN, InN, and AlInGaN may be used. Alternatively, a semiconductor element layer, which is different from a nitride semiconductor, and which includes layers made of GaAs, AlGaAs, InGaP, AlInGaP and the like may be used.

Thus, it is a matter of course that the present invention includes various embodiments and the like which are not described here. Accordingly, the technical scope of the present invention is defined only by the limitations of the appended claims consistent with the above description.

What is claimed is:

1. A semiconductor laser element comprising:
a semiconductor layer formed on a substrate, the semiconductor layer includes a raised portion and flat portions, the raised portion extends along a predetermined direction, the flat portions are provided on outer sides in a width direction of the raised portion;
an insulating layer formed on upper surfaces of the flat portions and side surfaces of the raised portion; and
an electrode including a first portion and a second portion, the first portion is provided along the predetermined direction on the raised portion, the second portion includes a plurality of protruding portions protruding outward from the first portion in the width direction of the raised portion, wherein,
the raised portion is a current injection region into which current is injected from the electrode,
the plurality of protruding portions are provided on the insulating layer, and
a gap through which the insulating layer is exposed is provided between each adjacent two of the plurality of protruding portions.

2. The semiconductor laser element according to claim 1, wherein the electrode has a comb-like shape in which end portions of the plurality of protruding portions on outer sides in the width direction of the raised portion are separated from one another.

3. The semiconductor laser element according to claim 2, wherein at least one of the plurality of protruding portions has a shape having a width greater than 10 μm in the predetermined direction.

4. The semiconductor laser element according to claim 2, wherein a width of each of the protruding portions in the predetermined direction is not more than a width of each of the gaps in the predetermined direction.

5. A semiconductor laser element comprising:
a semiconductor layer formed on a substrate, the semiconductor layer includes a raised portion and flat portions, the raised portion extends along a predetermined direction, the flat portions are provided on outer sides in a width direction of the raised portion;
an insulating layer formed on upper surfaces of the flat portions and side surfaces of the raised portion; and
an electrode comprising a first portion and a second portion, the first portion is provided along the predetermined direction on the raised portion, the second portion includes a protruding portion protruding outward from the first portion in the width direction of the raised portion, wherein,
the raised portion is a current injection region into which current is injected from the electrode,
the protruding portion is provided on the insulating layer,
an island-shaped bonding portion is provided on the insulating layer, the bonding portion is apart from the electrode, and
the bonding portion is adjacent to the protruding portion.

6. The semiconductor laser element according to claim 1, wherein the protruding portion is provided on a side close to a facet from which laser light emitted by the semiconductor layer is emitted.

7. The semiconductor laser element according to claim 5, wherein the protruding portion is provided on a side close to a facet from which laser light emitted by the semiconductor layer is emitted.

8. The semiconductor laser element according to claim 6, wherein the facet from which the laser light is emitted is an M-plane surface.

9. The semiconductor laser element according to claim 7, wherein the s facet from which the laser light is emitted is an M-plane surface.

10. The semiconductor laser element according to claim 1, wherein,
the substrate is a GaN substrate or a sapphire substrate, and
the semiconductor layer is a nitride semiconductor layer having a hexagonal crystal structure.

11. The semiconductor laser element according to claim 5, wherein,
the substrate is a GaN substrate or a sapphire substrate, and
the semiconductor layer is a nitride semiconductor layer having a hexagonal crystal structure.

12. A semiconductor laser device comprising:
the semiconductor laser element according to claim 1; and
at least one conductive wire,
wherein the conductive wire is connected to the plurality of protruding portions.

13. A semiconductor laser device comprising:
the semiconductor laser element according to claim 2; and
at least one conductive wire,
wherein the conductive wire is connected to the plurality of protruding portions.

14. A semiconductor laser device comprising:
the semiconductor laser element according to claim 3; and
at least one conductive wire,
wherein the conductive wire is connected to the plurality of protruding portions.

15. A semiconductor laser device comprising:
the semiconductor laser element according to claim 4; and
at least one conductive wire,
wherein the conductive wire is connected to the plurality of protruding portions.

16. A semiconductor laser device comprising:
the semiconductor laser element according to claim 5; and
at least one conductive wire,
wherein the conductive wire is connected to both the protruding portion and the bonding portion.

17. A semiconductor laser device comprising:
the semiconductor laser element according to claim 6; and
at least one conductive wire,
wherein the conductive wire is connected to both the protruding portion and the bonding portion.

18. A semiconductor laser device comprising:
the semiconductor laser element according to claim 7; and
at least one conductive wire,
wherein the conductive wire is connected to both the protruding portion and the bonding portion.
